(19) United States
(12) Patent Application Publication
(10) Pub. No.: US 2025/0192027 A1
(43) Pub. Date: Jun. 12, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventor: Chih-Hsiang Yao, Hsinchu (TW)

(73) Assignee: Taiwan Semiconductor Manufacturing Company, Ltd., Hsinchu (TW)

(21) Appl. No.: 18/403,587

(22) Filed: Jan. 3, 2024

Related U.S. Application Data
(60) Provisional application No. 63/608,293, filed on Dec. 10, 2023.

(51) Int. Cl. H01L 23/522; H01L 23/00; H01L 23/498; H01L 23/58

(52) U.S. Cl. CPC H01L 23/5226; H01L 23/49838; H01L 23/585; H01L 23/564

(57) ABSTRACT

A semiconductor device includes a substrate, an interconnect, and a vertical connection structure. The substrate has a front-side and a back-side. The interconnect is disposed over the front-side of the substrate. The vertical connection structure is embedded in the interconnect and penetrates through the substrate, and the vertical connection structure includes a first portion and a second portion. The first portion is embedded inside the interconnect and further extends into the substrate. The second portion is disposed in the substrate and extends from the back-side to the first portion, and the second portion is in contact with the first portion. An aspect ratio of the second portion is less than an aspect ratio of the first portion.

### CROSS-REFERENCE TO RELATED APPLICATION

This application claims the priority benefit of U.S. provisional application Ser. No. 63/608,293, filed on Dec. 10, 2023. The entirety of the above-mentioned patent application is hereby incorporated by reference herein and made a part of this specification.

### BACKGROUND

Developments in shrinking sizes of semiconductor devices and electronic components make the integration of more devices and components into a given volume possible and lead to high integration density of various semiconductor devices and/or electronic components.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 23 are schematic plane or cross-sectional views of various stages in a manufacturing method of a semiconductor device in accordance with some embodiments of the disclosure.

FIG. 24 is a schematic cross-sectional view showing a semiconductor device in accordance with alternative embodiments of the disclosure.

FIG. 25 through FIG. 28 are enlarged and schematic cross-sectional views respectively showing a part of a semiconductor device in accordance with some embodiments of the disclosure.

FIG. 29 and FIG. 30 are schematic plane or cross-sectional views showing a semiconductor device in accordance with some embodiments of the disclosure.

FIG. 31 is a schematic cross-sectional view showing a semiconductor device in accordance with alternative embodiments of the disclosure.

FIG. 32 through FIG. 35 are enlarged and schematic cross-sectional views respectively showing a part of a semiconductor device in accordance with some embodiments of the disclosure.

FIG. 36 is a schematic cross-sectional view showing a semiconductor device in accordance with some embodiments of the disclosure.

FIG. 37 is a flow chart illustrating a method for manufacturing a semiconductor device in accordance with some embodiments of the disclosure.

FIG. 38 is a schematic cross-sectional view showing an application of a semiconductor device in accordance with some embodiments of the disclosure.

FIG. 39 is a schematic plane view showing a part of a semiconductor device in accordance with alternative embodiments of the disclosure.

FIG. 40 is a schematic plane view showing a part of a semiconductor device in accordance with alternative embodiments of the disclosure.

FIG. 41 is a schematic cross-sectional views showing a semiconductor device in accordance with some alternative embodiments of the disclosure.

FIG. 42 is a schematic plane view showing a part of a semiconductor device in accordance with alternative embodiments of the disclosure.

FIG. 43 is a schematic plane view showing a part of a semiconductor device in accordance with alternative embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The specific embodiment(s) described herein is related to a semiconductor device (or a semiconductor package or structure) having a vertical connection structure penetrating through a substrate, and is not intended to limit the scope of the disclosure. In embodiments of the disclosure, the vertical connection structure includes a first portion having a first lateral size and a second portion having a second lateral size greater than the first lateral size, where the first portion is disposed inside the substrate and extended into to the interconnect disposed at a frontside of the substrate, the second portion is disposed inside the substrate and extended towards to and stopped at a backside of the substrate, and the first portion is connected to the second portion. Due to the first portion of the vertical connection structure, a critical dimension (CD) of the vertical connection structure at the frontside of the substrate maintains the same, so that the integration level of the semiconductor device is secured; while due to the second portion of the vertical connection structure, an aspect ratio of the second portion of the vertical connection structure is less than an aspect ratio of the first portion of the vertical connection structure, so that a contact resistance (Rc) can be lowered.

In addition, due to a two-step formation of the vertical connection structure, a thickness of the substrate can be still thick enough to obtain a good thermal dissipation and a better warpage of the semiconductor device. In embodiments of the disclosure, the vertical connection structure is laterally surrounded by a ring wall (or a guard ring wall) disposed inside the interconnect. Due to the ring wall, metal features of the interconnect can be well-protected from moisture attacks during forming the first portion of the vertical connection structure. In embodiments of the disclosure, the first portion and the second portion of the vertical connection structure are in a one-to-one configuration, where such vertical connection structure can be utilized for transmitting signals, ground power or small power. The first portion and the second portion of the vertical connection structure are in a multiple-to-one configuration, where such vertical connection structure can be utilized for transmitting power.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

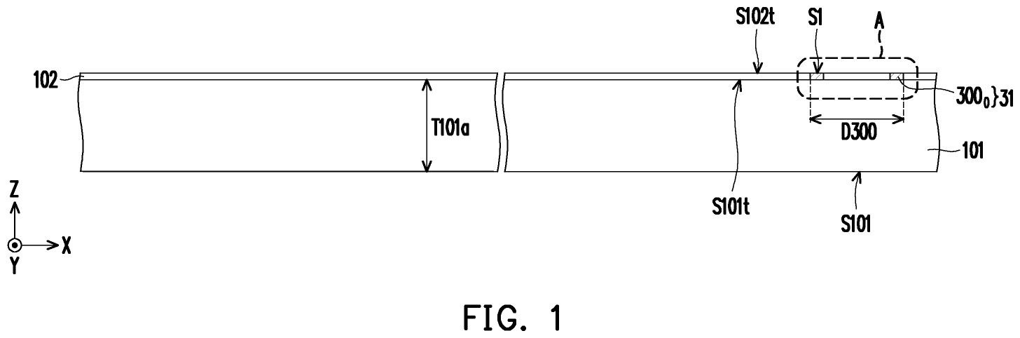

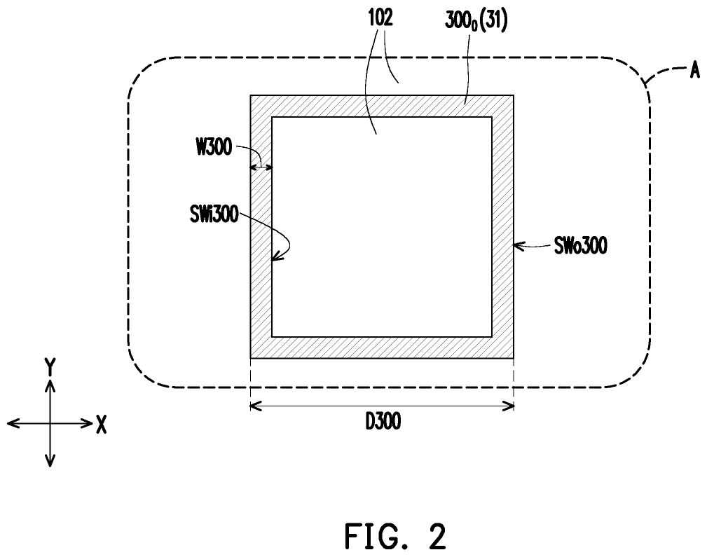

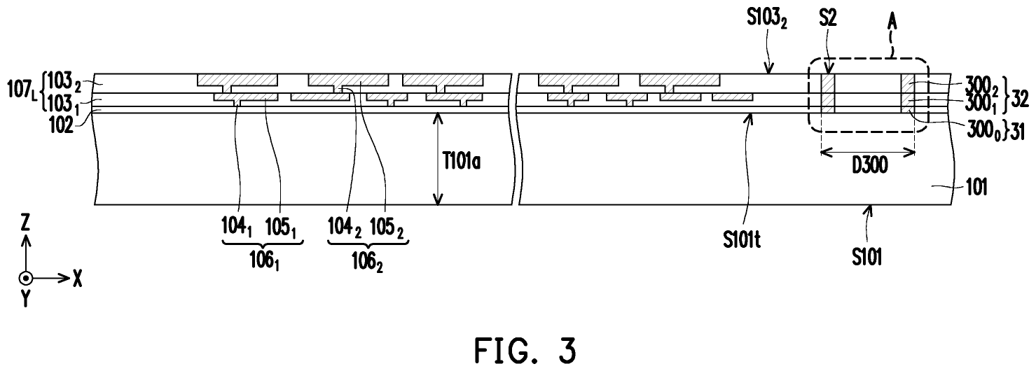

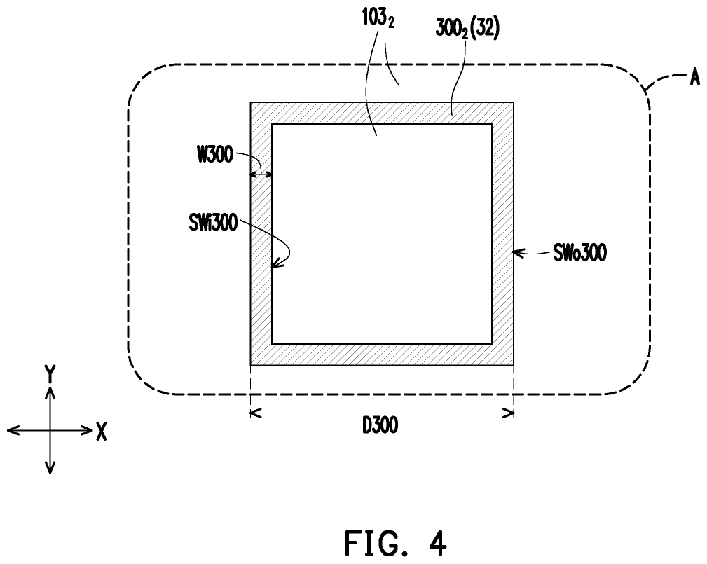

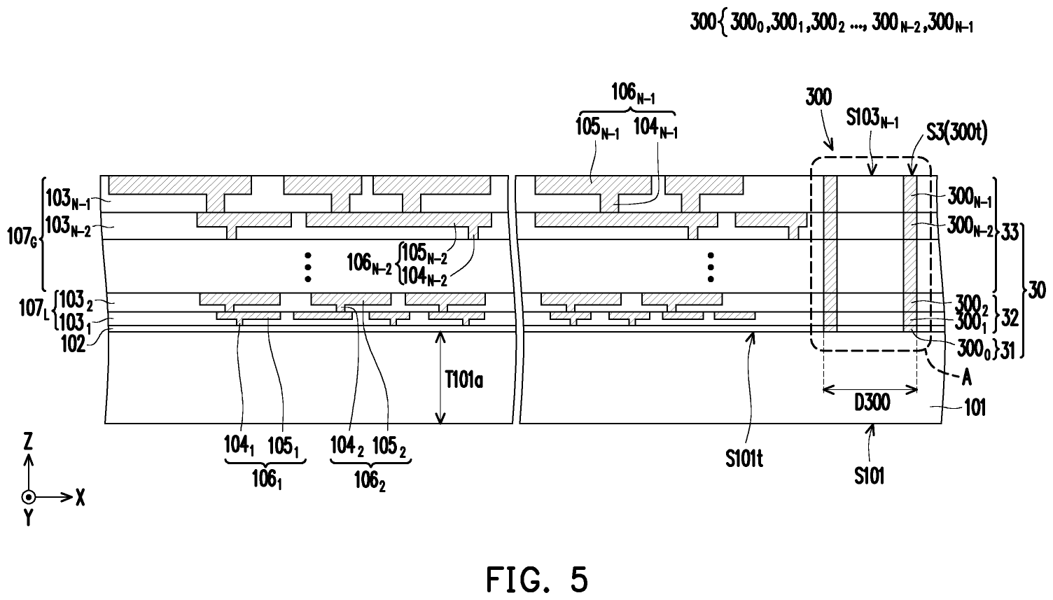

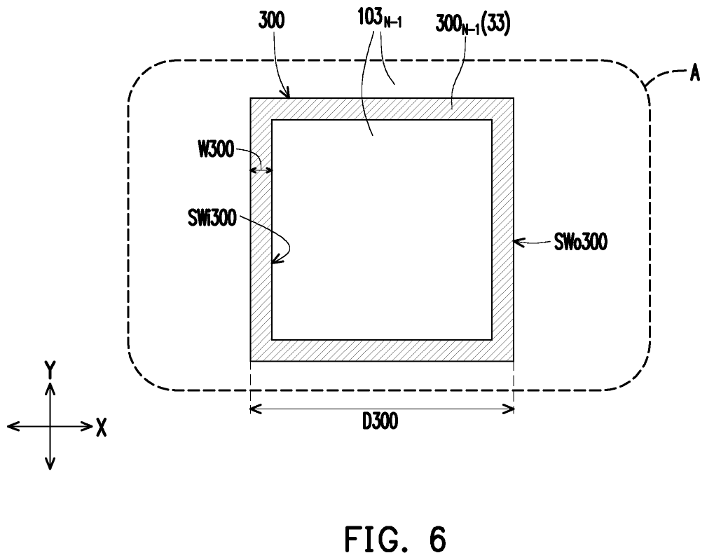

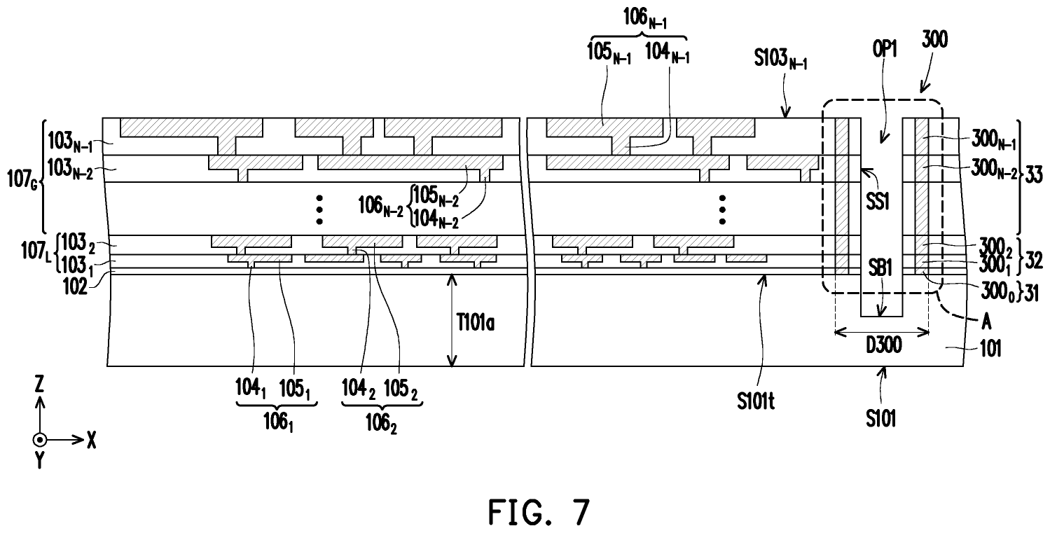

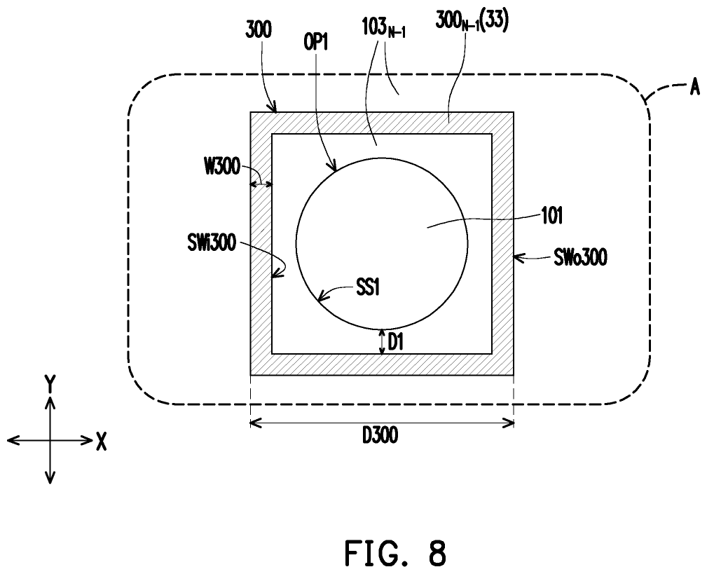

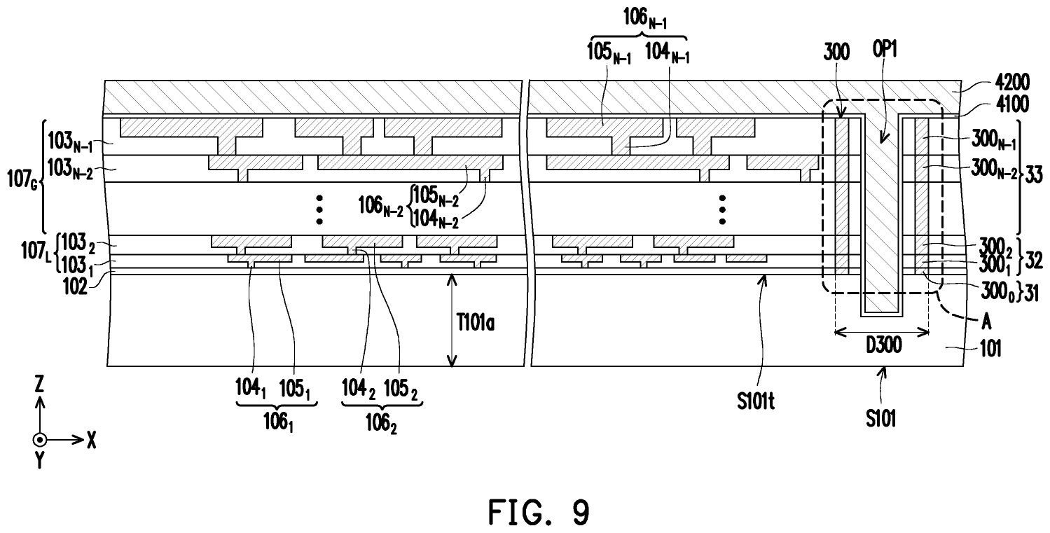

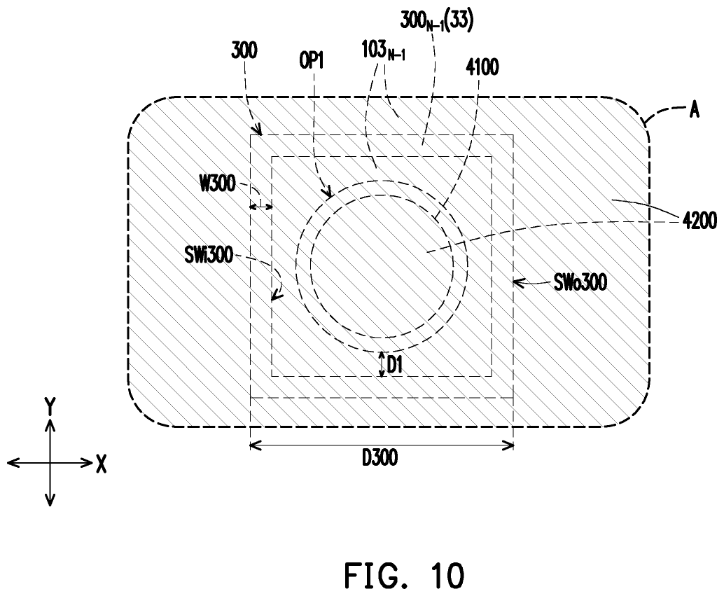

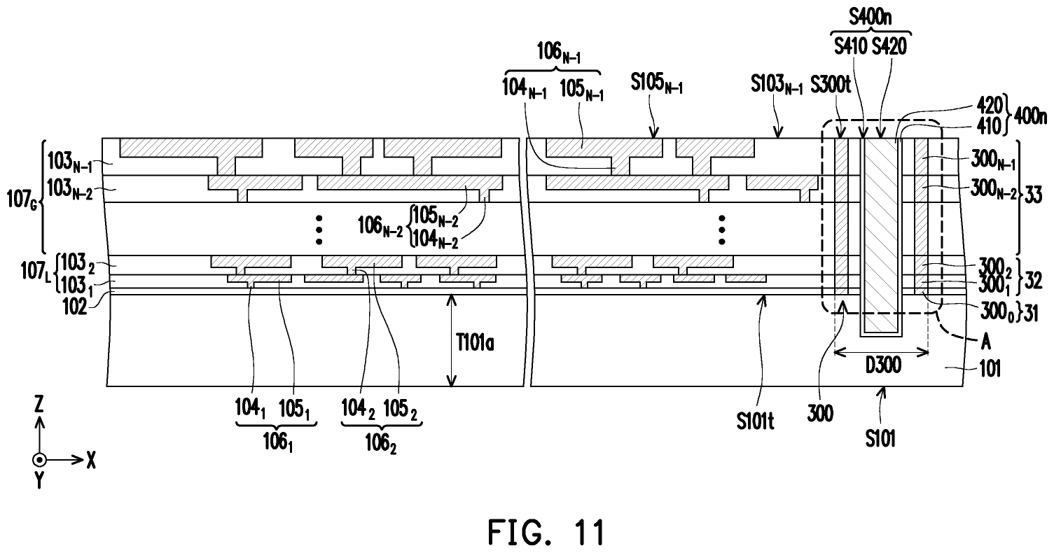

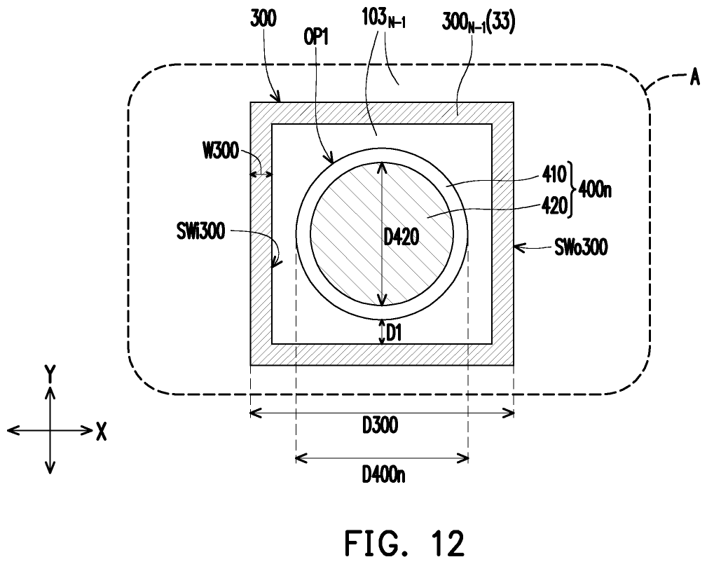

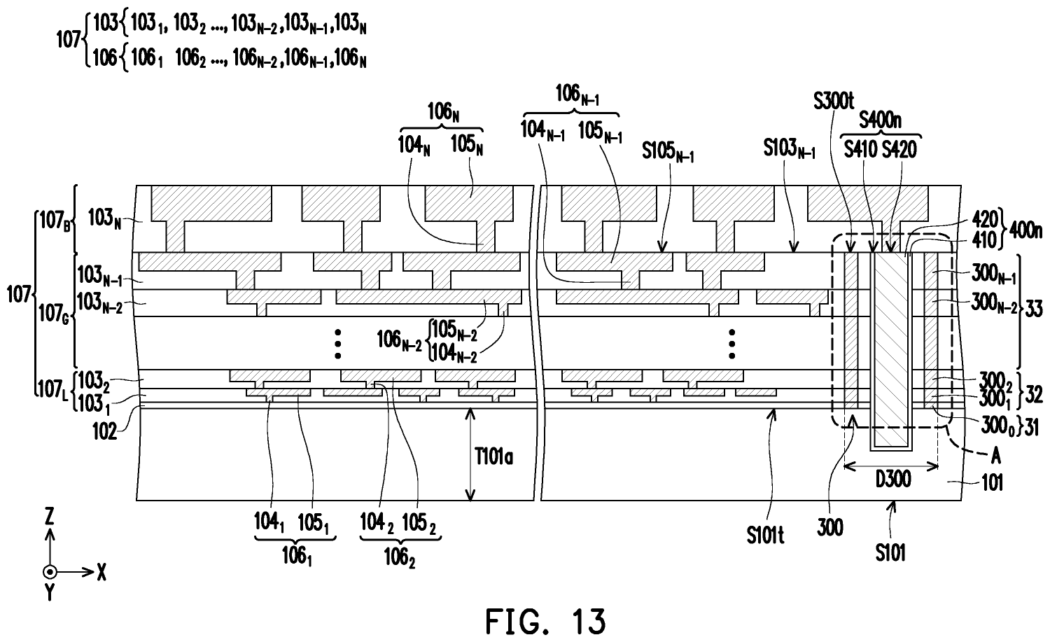

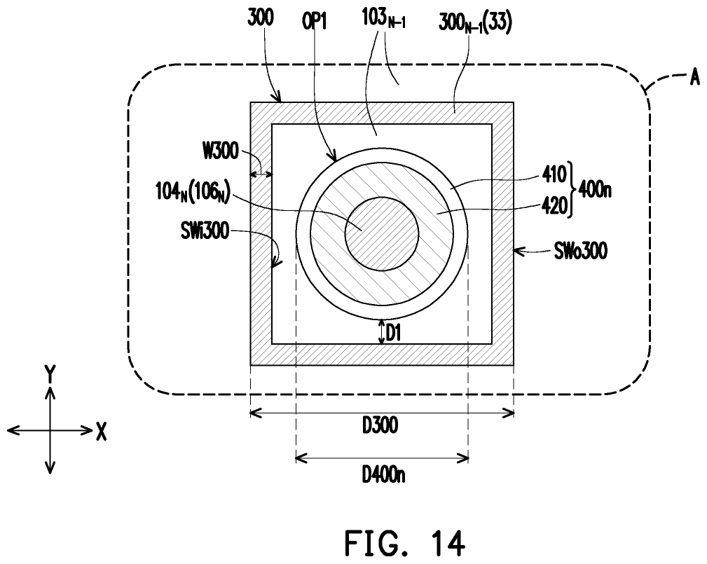

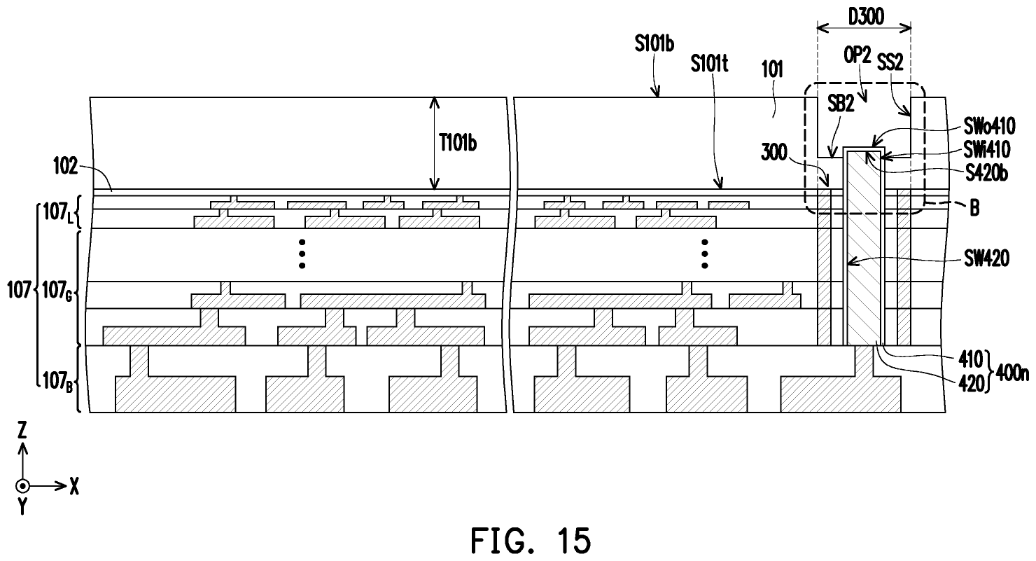

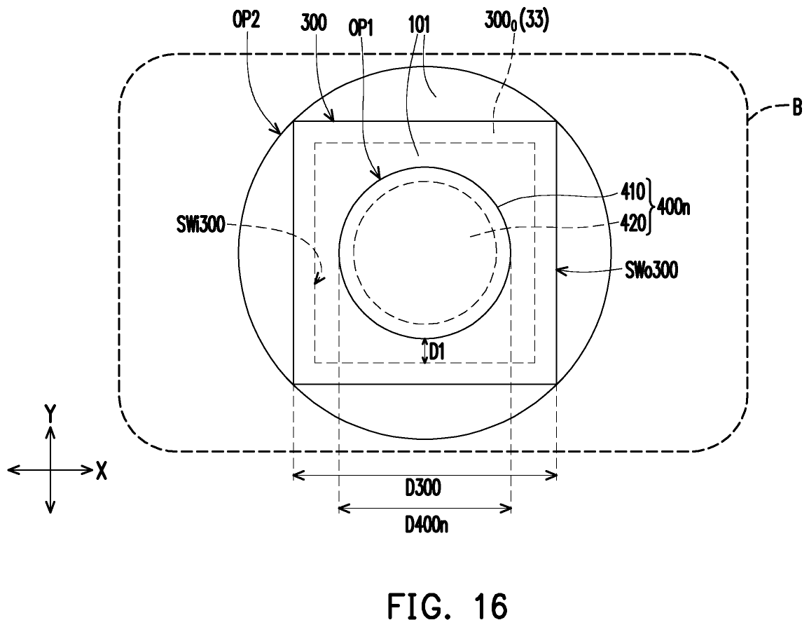

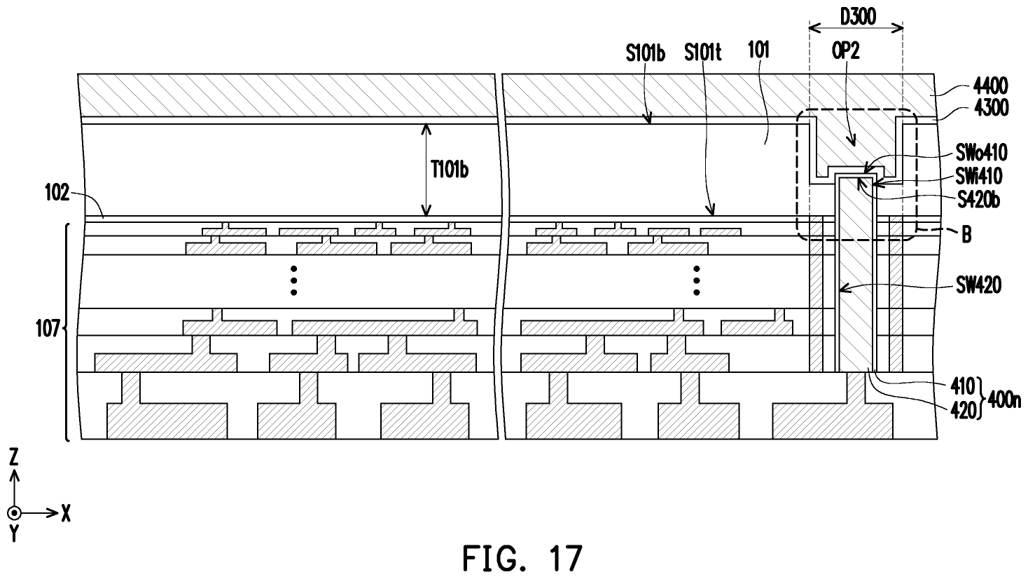

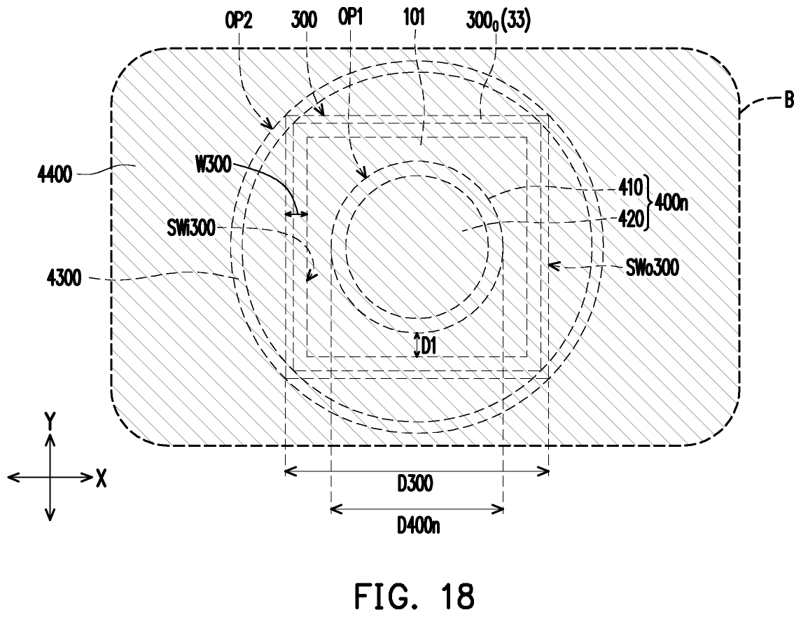

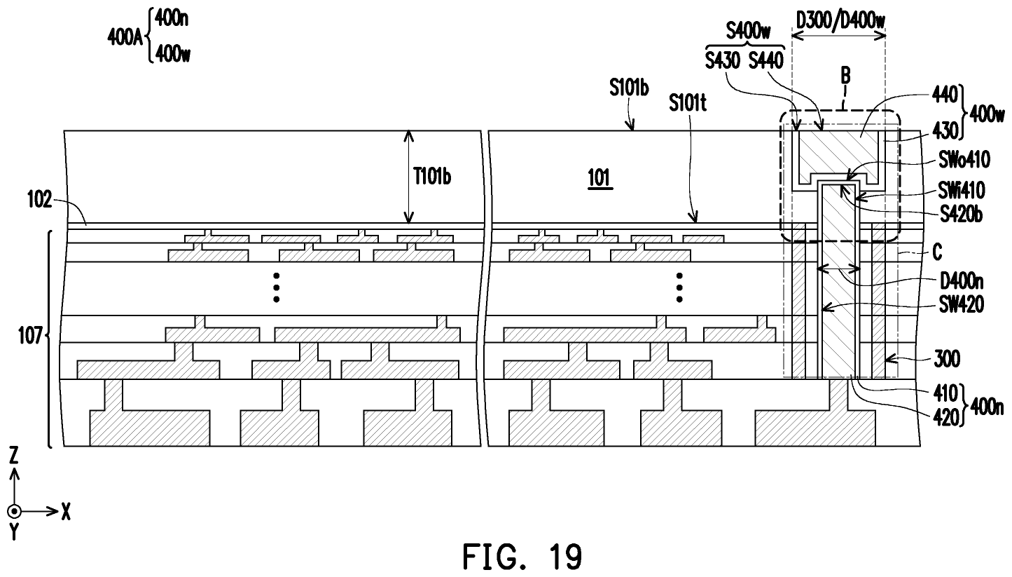

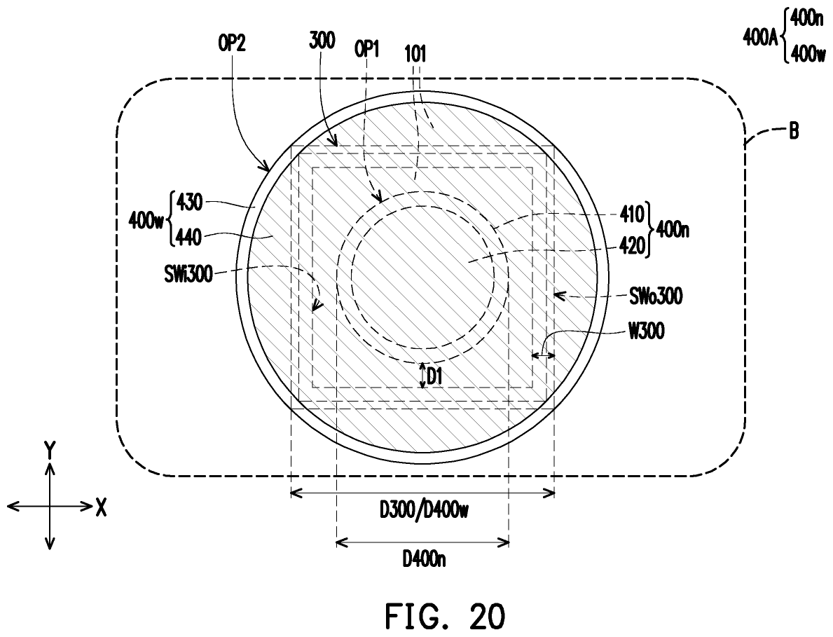

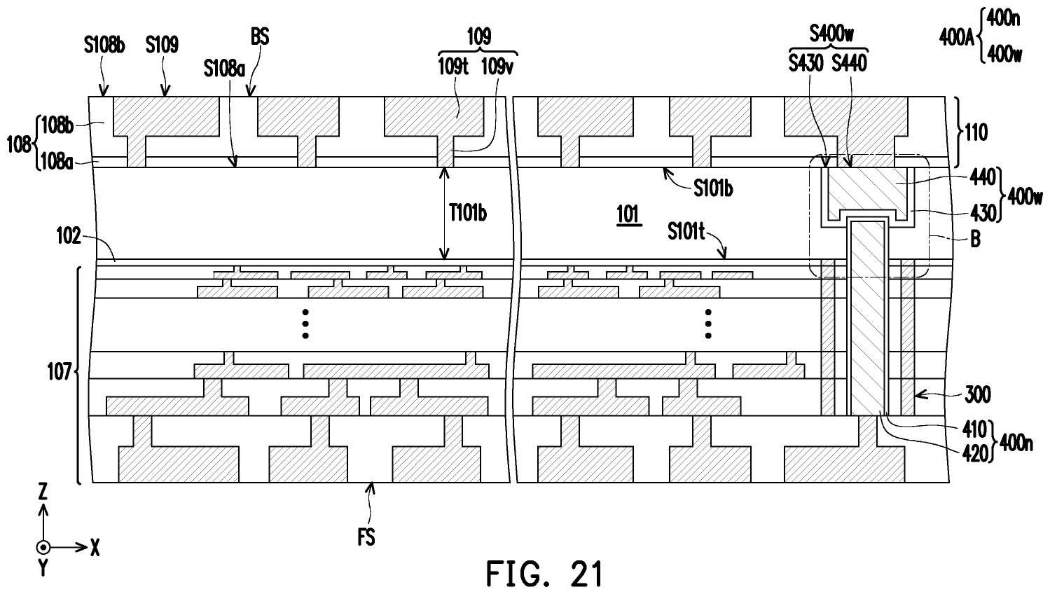

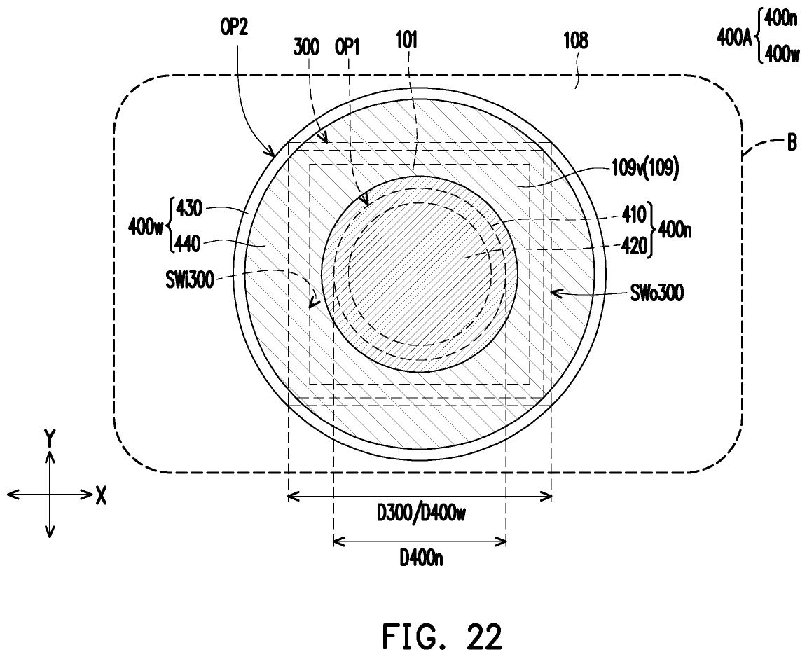

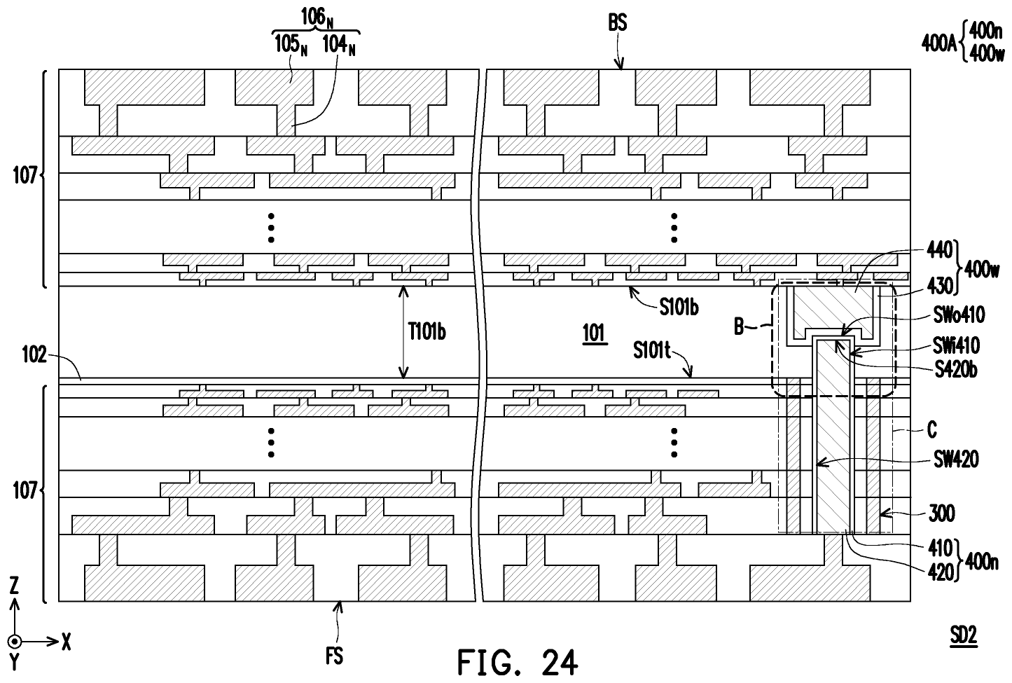

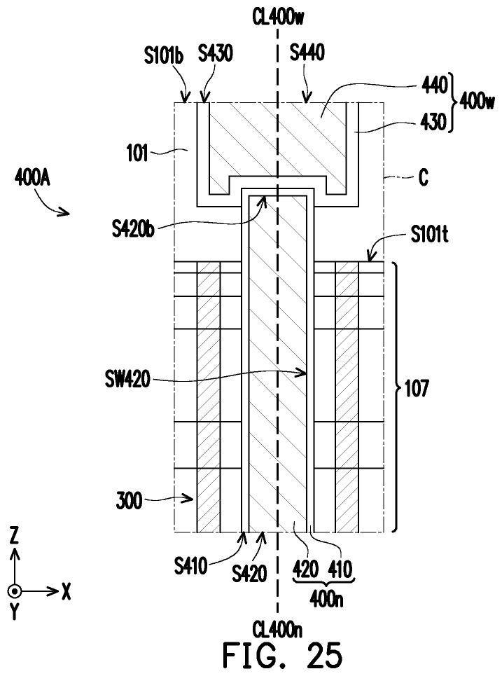

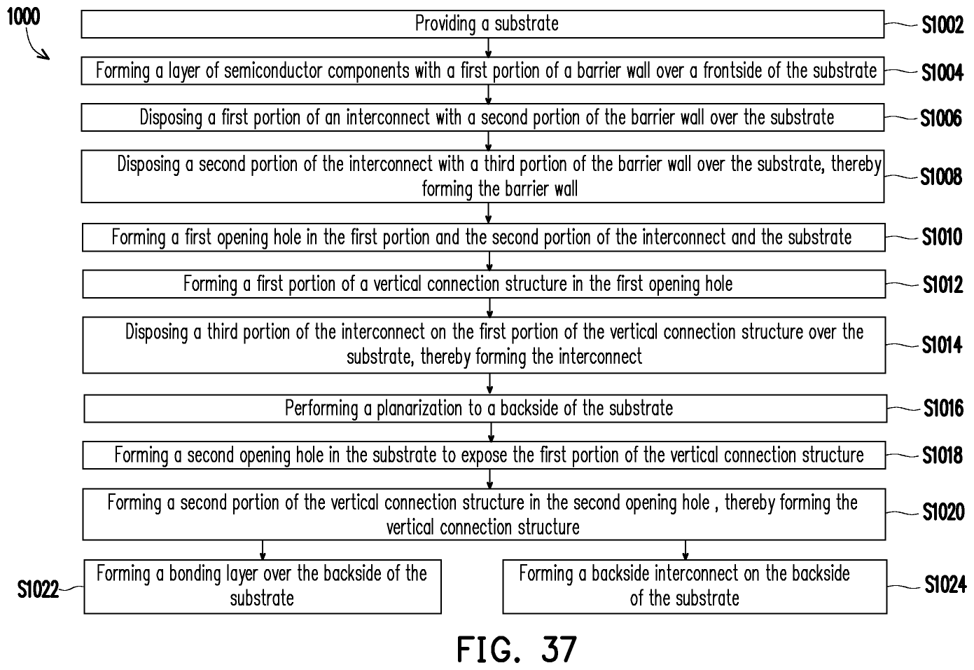

FIG. 1 to FIG. 23 are schematic plane or cross-sectional views of various stages in a manufacturing method of a semiconductor device (e.g., SD1) in accordance with some embodiments of the disclosure, where the schematic plane views of FIG. 2, FIG. 4, FIG. 6, FIG. 8, FIG. 10, FIG. 12 and FIG. 14 are respectively outlined by a dash-box A depicted in the schematic cross-sectional views of FIG. 1, FIG. 3, FIG. 5, FIG. 7, FIG. 9, FIG. 11 and FIG. 13, and the schematic plane views of FIG. 16, FIG. 18, FIG. 20 and FIG. 22 are respectively outlined by a dash-box B depicted in the schematic cross-sectional views of FIG. 15, FIG. 17, FIG. 19 and FIG. 21. FIG. 24 is a schematic cross-sectional view showing a semiconductor device (e.g., SD2) in accordance with alternative embodiments of the disclosure. FIG. 25 to FIG. 28 are schematic, enlarged cross-sectional views respectively showing a part (e.g., outlined by a dash-box C depicted in FIG. 19 and/or FIG. 24) of a semiconductor device (e.g., SD1 and/or SD2) in accordance with some embodiments of the disclosure. FIG. 37 is a flow chart illustrating a method (e.g., 1000) for manufacturing a semiconductor device in accordance with some embodiments of the disclosure. The embodiments are intended to provide further explanations but are not used to limit the scope of the disclosure.

Referring to FIG. 1, in some embodiments, a substrate 101 is provided, in accordance with a step S1002 of a method 1000 depicted in FIG. 37. In some embodiments, the substrate 101 includes a bulk semiconductor substrate, a crystalline silicon substrate, a doped semiconductor substrate (e.g., p-type semiconductor substrate or n-type semiconductor substrate), a semiconductor-on-insulator (SOI) substrate, or the like. In certain embodiments, the substrate 101 includes one or more doped regions or various types of doped regions, depending on design requirements. In some embodiments, the doped regions are doped with p-type and/or n-type dopants. For example, the p-type dopants are boron or BF₂ and the n-type dopants are phosphorus or arsenic. The doped regions may be configured for an n-type metal-oxide-semiconductor (NMOS) transistor or a p-type MOS (PMOS) transistor. The substrate 101 may be a silicon wafer. Generally, the SOI substrate is a layer of a semiconductor material formed on an insulator layer. The insulator layer is, for example, a buried oxide (BOX) layer, a silicon oxide layer, or the like. Other substrates, such as a multi-layered or a gradient substrate, may also be used. In some alternative embodiments, the substrate 101 includes a semiconductor substrate made of an elemental semiconductor (such as diamond or germanium in a crystalline, a polycrystalline, or an amorphous structure, etc.); a compound semiconductor (such as gallium arsenide, silicon carbide, gallium phosphide, indium phosphide, indium arsenide and/or indium antimonide), an alloy semiconductor (such as silicon-germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), etc.), combinations thereof, or other suitable materials. For example, the substrate 101 is a silicon bulk substrate. The compound semiconductor substrate may have a multilayer structure, or may include a multilayer compound semiconductor structure. The alloy SiGe may be formed over a silicon substrate. The SiGe substrate may be strained. The substrate 101 has a surface S101t and a surface S101 opposing to the surface S101t in the direction Z, as shown in FIG. 1, for example. A thickness of the substrate 101 (as measured in the direction Z) may be approximately from 20 μm to 1100 μm, for example, from 20 μm to 100 μm, from 100 μm to 700 μm, or from 700 μm to 1100 μm; although other suitable thickness may alternatively be utilized. For example, the thickness of the substrate 101 is about 775 μm, if considering the size of the substrate 101 is in a form of wafer-size having a diameter of about 12 inches.

Continued on FIG. 1, in some embodiments, a device layer 102 is disposed over the substrate 101, in accordance with a step S1004 of the method 1000 depicted in FIG. 37. One or more components (not shown) formed in the device layer 102 may be or include active components, passive components, other suitable electrical components, and/or combinations thereof. The components may include integrated circuit (IC) devices. The components may include transistors, capacitors, resistors, diodes, photodiodes, fuse devices, jumpers, inductors, or other similar devices. The functions of the components may include memories, processors, sensors, amplifiers, power distributions, input/output circuitries, or the like. The components each may be referred to as a semiconductor component of the disclosure. In some embodiments, the components are formed in the device layer 102 disposed at the surface S101t of the substrate 101, the components are formed in the device layer 102 disposed at the surface S101t of the substrate 101 and further partially extended into the substrate 101, or a combination thereof. The surface S101t of the substrate 101 may be referred to as an active surface or a front-side of the substrate 101, and the surface S101 of the substrate 101 may be referred to as a non-active surface, a back-side or a rear-side of the substrate 101. In some embodiments, the device layer 102 is overlaid on (e.g., in physical contact with) the active surface or front-side (e.g. S101t) of the substrate 101. The device layer 102 are formed in a front-end-of-line (FEOL) fabrication processes.

In some embodiments, the device layer 102 further includes one or more metal features (not shown) formed in the FEOL fabrication processes, where the components (may be further referred to as FEOL components or FEOL semiconductor components) and the metal features (may be referred to as FEOL metal features, FEOL metal contacts or FEOL metallic contacts) are protected by a dielectric (may be referred to as a FEOL dielectric) formed in the FEOL fabrication processes. The components may include transistors, where the metal features may include source contacts, drain contacts, and gate contacts respectively being electrically coupled to sources, drains and gates of the transistors. In the device layer 102, the dielectric (may be referred to as a FEOL dielectric, a FEOL dielectric layer, or an interlayer dielectric (ILD), an ILD layer, a FEOL ILD or a FEOL ILD layer) may cover the components, and at least some of the metal feature may penetrate through the dielectric to be in contact with the components. In some embodiments, the metal features provide electrical connections between the components formed in the device layer 102 and metal features formed in a later-formed interconnect (e.g., 107 in FIG. 13) disposed on the device layer 102 and over the surface S101t of the substrate 101. For example, the device layer 102 may be formed by, but not limited to, forming the components of the device layer 102 over the surface S101t of the substrate 101, disposing the dielectric of the device layer 102 on the components of the device layer 102, patterning the dielectric of the device layer 102 to form a plurality of through holes to accessibly expose portions of the components, and forming the metal features of the device layer 102 in the plurality of through holes formed in the dielectric of the device layer 102 to be electrically coupled with the components of the device layer 102. A planarization process may be performed to level an outermost surface of the device layer 102 to facilitate the formation of the later-formed interconnect (e.g., 107 in FIG. 13).

The metal features of the device layer 102 may include copper (Cu), copper alloys, nickel (Ni), aluminum (Al), manganese (Mn), magnesium (Mg), silver (Ag), gold (Au), tungsten (W), ruthenium (Ru), cobalt (Co), titanium (Ti), titanium nitride (TiN), combinations thereof, or the like. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc. The metal features of the device layer 102 may be formed by, for example, plating such as electroplating or electroless plating, chemical vapor deposition (CVD) such as plasma enhanced CVD (PECVD), atomic layer deposition (ALD), physical vapor deposition (PVD), a combination thereof, or the like. The disclosure is not limited thereto.

The dielectric of the device layer 102 may include oxides, low-K (LK), ultra low-K (ULK), extra low-K (ELK) and XLK materials. The material classification is based upon capacitance or dielectric constant value (e.g., k value), with the LK materials usually referring to those materials with a k value between about 3.1 to 2.7, the ULK materials usually referring to those materials with a k value between about 2.7 to 2.4, and the ELK materials usually referring to those materials with a k value between about 2.3 to 2.0. In addition, the XLK materials refers to a porous HSQ-based dielectric material which typically has a k value less than about 2.0. In a non-limiting example, the dielectric of the device layer 102 include oxides, the LK materials, combination thereof, or the like. It is understood that the dielectric of the device layer 102 may include one or more dielectric materials. For example, the dielectric of the device layer 102 include a single-layer structure or a multilayer structure. In some embodiments, the dielectric of the device layer 102 is formed to a suitable thickness by CVD such as flowable chemical vapor deposition (FCVD), high-density plasma CVD (HDP-CVD) and sub-atmospheric CVD (SACVD), spin-on, sputtering, or other suitable methods.

A seed layer (not shown) may be optionally formed between the dielectric of the device layer 102 and the metal features of the device layer 102. That is, for example, the seed layer covers a bottom surface and sidewalls of each of the metal features of the device layer 102. In some embodiments, the seed layer is a metal layer, which may be a single layer or a composite layer comprising a plurality of sub-layers formed of different materials. In some embodiments, the seed layer includes a copper layer. In some embodiments, the seed layer includes a titanium layer and a copper layer over the titanium layer. The seed layer may be formed using, for example, PVD or the like. Alternatively, the seed layer may be omitted.

In addition, an additional barrier layer or adhesive layer (not shown) may be optionally formed between the metal features of the device layer 102 and the dielectric of the device layer 102. Owing to the additional barrier layer or adhesive layer, it is able to prevent the seed layer and/or the metal features of the device layer 102 from diffusing to the underlying layers and/or the surrounding layers. The additional barrier layer or adhesive layer may include Ti, TIN, Ta, TaN, a combination thereof, a multilayer thereof, or the like, and may be formed using CVD, ALD, PVD, a combination thereof, or the like. In an alternative embodiment of which the seed layer is included, the additional barrier layer or adhesive layer is interposed between the dielectric of the device layer 102 and the seed layer, and the seed layer is interposed between the metal features of the device layer 102 and the additional barrier layer or adhesive layer. Alternatively, the additional barrier layer or adhesive layer may be omitted.

In some embodiments, as illustrated in FIG. 1 and FIG. 2, a first portion 31 of a ring wall (e.g., 300 in FIG. 5) is formed in the device layer 102 over the substrate 101, in accordance with the step S1004 of the method 1000 depicted in FIG. 37. The first portion 31 of the ring wall 300 includes a sub-layer 300₀, in some embodiments. The first portion 31 of the ring wall 300 may penetrate through the device layer 102, as shown in FIG. 1. For example, a surface S1 of the sub-layer 300₀ of the ring wall 300 is accessibly revealed by a surface S102t of the device layer 102. In some embodiments, the surface S1 of the sub-layer 300₀ of the ring wall 300 is substantially level with the surface S102t of the device layer 102. That is, the surface S1 of the sub-layer 300₀ of the ring wall 300 may be substantially coplanar to the surface S102t of the device layer 102, as shown in FIG. 1. In some embodiments, as shown in a plane view of FIG. 2 in conjunction with the part outlined by the dash-box A in the cross-sectional view of FIG. 1, the first portion 31 (e.g., the sub-layer 300₀) of the ring wall 300 is in a form of square-shape with an outer sidewall SWo300 and an inner sidewall SWi300 opposing to the outer sidewall SWo300 in a lateral direction (e.g. a direction X and a direction Y). The direction X may be different from the direction Y, and the directions X and Y may be different from Z. For example, the direction X is perpendicular to the direction Y, and the directions X and Y are perpendicular to the direction Z. In the plane view of FIG. 2, a width W300 (e.g. a minimum distance laterally measured between the outer sidewall SWo300 and the inner sidewall SWi300) of the first portion 31 (e.g., the sub-layer 300₀) of the ring wall 300 is approximately from 1 μm to 3 μm, although other suitable thickness may alternatively be utilized. In the plane view of FIG. 2, an outer diameter D300 of the first portion 31 (e.g., the sub-layer 300₀) of the ring wall 300 is approximately from 2.5 μm to 7.5 μm, although other suitable outer diameter may alternatively be utilized.

The formation and material of the first portion 31 (e.g., the sub-layer 300₀) of the ring wall 300 may be similar to or substantially identical to the forming process and materials of the metal features (with or without the optional seed layer) of the device layer 102 previously described in FIG. 1 and FIG. 2, and thus are not repeated therein. In some embodiments, the sub-layer 300₀ of the ring wall 300 is spacing apart from the components and the metal features of the device layer 102 by the dielectric of the device layer 102. In other words, the dielectric of the device layer 102 laterally covers the sub-layer 300₀ of the ring wall 300. In some embodiments, an optional seed layer may be optionally formed to cover an illustrated bottom surface, an inner sidewall and an outer sidewall of the sub-layer 300₀ of the ring wall 300. For example, the sub-layer 300₀ of the ring wall 300 and the metal features of the device layer 102, which are located at the same elevation level from the surface S101t of the substrate 101, are formed in the same step. However, the disclosure is not limited thereto. Alternatively, the sub-layer 300₀ of the ring wall 300 and the metal features of the device layer 102, which being located at the same elevation level from the surface S101t of the substrate 101, may be formed in different steps. The number of the build-up layer(s) included in the first portion 31 of the ring wall 300 may include one, two, three or more than three, depending on the demand and the design requirement, as long as the first portion 31 of the ring wall 300 can completely penetrate through the device layer 102. For example, the number of the build-up layer(s) included in the first portion 31 of the ring wall 300 is the same as the number of the layer(s) of the metal features included in the device layer 102.

In some embodiments, an interconnect 107 (in FIG. 13) is formed on the device layer 102 over the surface S101t of the substrate 101, and the interconnect 107 is electrically coupled to the device layer 102 (e.g., electrically coupled to the components formed in the device layer 102 through the metal features formed in the device layer 102). That is, the interconnect 107 provides the routing functions to the components formed in the device layer 102 for electrical connections to external components by a first portion of the interconnect 107 providing a local interconnection (e.g., 107_{L} in FIG. 3), a second portion of the interconnect 10 providing a global interconnection (e.g., 107_{G} in FIG. 5) disposed thereon and connecting thereto, and a third portion of the interconnect 107 providing a bonding terminal (e.g., 107_{B} in FIG. 13) disposed thereon and connecting thereto, for example. In some embodiments, at least some of the components formed in the device layer 102 are electrically communicated to one another by the interconnect 107, such as by the first portion of the interconnect 107 (e.g., 1071, in FIG. 3). That is, the first portion of the interconnect 107 (e.g., 107_{L} in FIG. 3) may provide local interconnections among the components formed in the device layer 102, which may be referred to as a local interconnect of the interconnect 107. On the other hand, the second portion of the interconnect 107 (e.g., 107_{G} in FIG. 5) may provide global interconnections between the components formed in the device layer 102 and one or more external electrical components, which may be referred to as a global interconnect of the interconnect 107. In such case, the third portion of the interconnect 107 (e.g., 107_{B} in FIG. 13) may use to be bonded with the one or more external electrical components, which may be referred to as a bonding layer of the semiconductor device SD1. The third portion of the interconnect 107 serving as the bonding layer (e.g., 107_{B} in FIG. 13) may also considered as part of the global interconnect of the interconnect 107, sometimes. The details of the first portion of the interconnect 107 shown in FIG. 3 and FIG. 4, the second portion of the interconnect 107 shown in FIG. 6 and FIG. 7 and the third portion of the interconnect 107 shown in FIG. 13 and FIG. 14 will be described in greater details later.

The interconnect 107 may be referred to as an interconnection, a redistribution circuit structure, a redistribution structure, or a routing structure. The interconnect 107 may be overlaid over the device layer 102 and includes a plurality of build-up layers being electrically connecting there-between. In some embodiments, each build-up layer includes a dielectric layer 103 and a pattern conductive layer 106 formed therein. As shown in FIG. 13, the interconnect 107 may be formed on and electrically connected to the device layer 102. In some embodiments, the interconnect 107 includes one or more dielectric layers 103 (e.g., 103₁, 103₂, . . . , 103_{N-2}, 103_{N-1}, and 103_{N}) and one or more patterned conductive layers 106 (e.g., 106₁, 106₂, . . . , 106_{N-2}, 106_{N-1}, and 106_{N}). For example, each patterned conductive layer 106 (e.g., 106₁, 106₂, . . . , 106_{N-2}, 106_{N-1}, and 106_{N}) includes a line portion 105 (e.g., 105₁, 105₂, . . . , 105_{N-2}, 105_{N-1}, and 105_{N}) extending along a horizontal direction (e.g., the direction X or the direction Y), a via portion 104 (e.g., 104₁, 104₂, . . . , 104_{N-2}, 104_{N-1}, and 104_{N}) extending along a vertical direction (e.g., the direction Z), and/or a combination thereof. The patterned conductive layers 106 may be referred to as metallization layers or redistribution layers of the interconnect 107 to provide routing functions, and may be collectively referred to as a routing structure of the interconnect 107. The dielectric layers 103 may be collectively referred to as a dielectric structure of the interconnect 107 to provide protection for the routing structure, the metallization layers or redistribution layers of the interconnect 107. In some embodiments, in the interconnect 107, the dielectric layers (e.g., 103) and the patterned conductive layers (e.g., 106) are arranged (e.g., formed) in alternation. One dielectric layer and a respective one metallization layer together may be considered as one build-up layer (e.g., 103₁ and 106₁; 103₂ and 106₂; 103_{N-2} and 106_{N-2}; 103_{N-1} and 106_{N-1}; 103_{N} and 106_{N}; or the like) of the interconnect 107. As shown in FIG. 13, for example, a topmost layer (e.g., 106_{N}) of the patterned conductive layers 106 may be accessibly revealed by a topmost layer (e.g., 103_{N}) of the dielectric layers 103 for external connection. In the disclosure, the numbers of layers of the dielectric layers 103 and the patterned conductive layers 106 are not limited to what is depicted in FIG. 13, and may be selected and designated based on the demand and design layout. In some embodiments, line dimensions (e.g., thickness and width) of the patterned conductive layers 106 are gradually increased along the direction Z from a bottommost layer (e.g., proximal to the device layer 102) of the build-up layers towards the topmost layer of the build-up layers.

In some embodiments, the line portions 105 (e.g., 105₁, 105₂, . . . , 105_{N-2}, 105_{N-1}, and 105_{N}) extending along a horizontal direction (e.g., the direction X and/or Y) and/or the line portions 105 (e.g., 105₁, 105₂, . . . , 105_{N-2}, 105_{N-1}, and 105_{N}) extending along the horizontal direction (e.g., the direction X and/or Y) in addition to the via portions 104 (e.g., 104₁, 104₂, . . . , 104_{N-2}, 104_{N-1}, and 104_{N}) connecting to the line portions 105 (e.g., 105₁, 105₂, . . . , 105_{N-2}, 105_{N-1}, and 105_{N}) and extending along a vertical direction (e.g., the direction Z) are referred to as conductive patterns/segments of the patterned conductive layers 106. In one embodiment, the materials of the patterned conductive layers 106 (e.g., 106₁, 106₂, . . . , 106_{N-2}, 106_{N-1}, and 106_{N}) of the build-up layers are the same to each other. Alternatively, the materials of the patterned conductive layers 106 (e.g., 106₁, 106₂, . . . , 106_{N-2}, 106_{N-1}, and 106_{N}) of the different build-up layers may be different to one another. In addition, the line portions 105 (e.g., 105₁, 105₂, . . . , 105_{N-2}, 105_{N-1}, and 105_{N}) may be referred to as conductive lines, conductive traces, conductive trenches, metallization lines, routing lines or redistribution lines, and the via portions 104 (e.g., 104₁, 104₂, . . . , 104_{N-2}, 104_{N-1}, and 104_{N})) may be referred to as conductive vias, metallization vias, routing vias or redistribution vias.

In addition, one or more seed layers (not shown) may be included in the interconnect 107 to facilitate the formation of the patterned conductive layers 106, where the seed layers may be interposed between the patterned conductive layers 106 and the dielectric layers 103. In embodiment of which the seed layers are included, one patterned conductive layer 106 and a respective one seed layer (not shown) may be together referred to as a metallization layer or a redistribution layer of the interconnect 107 to provide routing functions. That is, with such embodiments, one patterned conductive layer 106 and a respective one seed layer (not shown) may be collectively referred to as a routing structure of the interconnect 107. For example, the seed layers each cover a bottom surface and sidewalls of each of the patterned conductive layers 106. In some embodiments, the seed layers independently are a metal or metal alloy layer, which may be a single layer or a composite layer comprising a plurality of sub-layers formed of different materials. The material of each of the seed layers may include titanium, copper, molybdenum, tungsten, titanium nitride, titanium tungsten, combinations thereof, or the like, which may be formed using, for example, sputtering, PVD, or the like. In some embodiments, the seed layers include a copper layer. In some embodiments, the seed layers independently a titanium layer and a copper layer over the titanium layer. Alternatively, the seed layers may be omitted.

Referring back to FIG. 3, in some embodiments, the first portion 107_{L} of the interconnect 107 is formed over the device layer 102 and the first portion 31 of the ring wall 300, in accordance with a step S1006 of the method 1000 depicted in FIG. 37. For illustrative purposes, in FIG. 3, the first portion 1071, of the interconnect 107 may include two build-up layers (e.g., 103₁ and 106₁, and 103₂ and 106₂), however, the disclosure is not limited thereto. The number of the build-up layer(s) included in the first portion 107_{L} of the interconnect 107 may include one, two, three or more than three, depending on the demand and the design requirement, as long as the first portion 107_{L} of the interconnect 107 can fulfill the requirement of providing local interconnection between the components of the device layer 102. The first portion 107_{L} of the interconnect 107 may be referred to as the local interconnect or local interconnection of the interconnect 107.

In some embodiments, the first portion 1071, of the interconnect 107 may be formed by, but not limited to, forming a blanket layer of first dielectric material over the device layer 102; patterning the first dielectric material blanket layer to form a dielectric layer 103₁ having a plurality of first openings (not labeled) penetrating there-through and accessibly revealing portions (e.g., the metal features) of the device layer 102; optionally forming a blanket layer of first seed layer material over the dielectric layer 103₁, the first seed layer material blanket layer extending into the first openings to line the first openings and in contact with the exposed portions of the device layer 102; forming a blanket layer of a first conductive material over the first seed layer material blanket layer; patterning the first conductive material blanket layer and the first seed layer material blanket layer by performing a planarization process to remove excess of the first conductive material blanket layer and the first seed layer material blanket layer located over an illustrated topmost surface of dielectric layer 103₁ in order to form the patterned conductive layer 106₁ and a first optional seed layer, thereby forming one build-up layer (e.g., a first build-up layer (not labeled) including 103₁ and 106₁); forming a blanket layer of second dielectric material over the patterned conductive layer 106₁, the dielectric layer 103₁ and the first optional seed layer (if any); patterning the second dielectric material blanket layer to form a dielectric layer 103₂ having a plurality of second openings (not labeled) penetrating there-through and accessibly revealing portions of an illustrated topmost surface of the patterned conductive layer 106₁; optionally forming a blanket layer of second seed layer material over the dielectric layer 103₂, the second seed layer material blanket layer extending into the second openings to line the second openings and in contact with the exposed portions of the patterned conductive layer 106₁; forming a blanket layer of a second conductive material over the second seed layer material blanket layer; patterning the second conductive material blanket layer and the second seed layer material blanket layer by performing another planarization process to remove excess of the second conductive material blanket layer and the second seed layer material blanket layer located over an uppermost surface of dielectric layer 103₂ in order to form the patterned conductive layer 106₂ and a second optional seed layer, thereby forming another build-up layer (e.g., a second build-up layer (not labeled) including 103₂ and 106₂). Upon this, the first portion 107_{L} of the interconnect 107 is manufactured. The first portion 107_{L} of the interconnect 107 may be formed on the device layer 102 by single or dual damascene process. The disclosure is not limited thereto. In some embodiments, the first portion 1071, of the interconnect 107 is formed in a middle-end-of-line (MEOL) fabrication processes. The planarization processes may individually include a grinding process, a chemical mechanical polishing (CMP) process, an etching process, or combinations thereof. The etching process may include a dry etching, a wet etching, or a combination thereof. The dielectric layers 103 included in the first portion 1071, of the interconnect 107 may be independently referred to as a MEOL dielectric, a MEOL dielectric layer, or an ILD, an ILD layer, a MEOL ILD or a MEOL ILD layer, and the patterned conductive layers 106 included in the first portion 107_{L} of the interconnect 107 may be independently referred to as a MEOL metal feature, a MEOL conductive layer, a MEOL metallization layer, or a MEOL redistribution layer, sometimes.

The formation and material of the dielectric layers 103 (e.g., 103₁ and 103₂) may be similar to or substantially identical to the forming process and materials of the dielectric of the device layer 102, and thus are not repeated herein for brevity. In a non-limiting example, the dielectric layers 103 (e.g., 103₁ and 103₂) include oxides, the LK materials, or combination thereof. In one embodiment, the materials of the dielectric layers 103 (e.g., 103₁ and 103₂) included in the first portion 1071, are the same to each other. Alternatively, the materials of the dielectric layers 103 (e.g., 103₁ and 103₂) included in the first portion 107_{L} may be different to one another, in part or all.

The formation and material of the patterned conductive layers 106 (e.g., 106₁ and 106₂) may be similar to or substantially identical to the forming process and materials of the metal features of the device layer 102, and thus are not repeated herein for brevity. In a non-limiting example, the patterned conductive layers 106 (e.g., 106₁ and 106₂) include Co, Ru, W, or the like. In one embodiment, the materials of the patterned conductive layers 106 (e.g., 106₁ and 106₂) in different build-up layers included in the first portion 107_{L} are the same to each other. Alternatively, the materials of the patterned conductive layers 106 (e.g., 106₁ and 106₂) in different build-up layers included in the first portion 107_{L} may be different to one another, in part or all.

In some embodiments, as illustrated in FIG. 3 and FIG. 4, a second portion 32 of the ring wall 300 is formed in the first portion 107_{L} of the interconnection 107 over the substrate 101, in accordance with the step S1006 of the method 1000 depicted in FIG. 37. The second portion 32 of the ring wall 300 includes a sub-layer 300₁ and a sub-layer 300₂ stacked thereon, in some embodiments. In such case, the sub-layer 300₁ is disposed on and electrically coupled to the sub-layer 300₀, and the sub-layer 300₂ is disposed on and electrically coupled to the sub-layer 300₁, where the sub-layer 300₁ is interposed between and electrically coupled to the sub-layer 300₀ and the sub-layer 300₂. The second portion 32 of the ring wall 300 may penetrate through the first portion 170_{L} of the interconnect 107, as shown in FIG. 3. In such case, the sub-layer 300₁ penetrates through the first build-up layer (including 103₁ and 106₁), and the sub-layer 300₂ penetrates through the second build-up layer (including 103₂ and 106₂). For example, a surface S2 of the sub-layer 300₂ of the ring wall 300 is accessibly revealed by a surface S1302 of the dielectric layer 1302. In some embodiments, the surface S2 of the sub-layer 300₂ of the ring wall 300 is substantially level with the surface S1032 of the dielectric layer 103₂. That is, the surface S2 of the sub-layer 300₂ of the ring wall 300 may be substantially coplanar to the surface S1032 of the dielectric layer 103₂, as shown in FIG. 3. In some embodiments, as shown in a plane view of FIG. 4 in conjunction with the part outlined by the dash-box A in the cross-sectional view of FIG. 3, the second portion 32 (e.g., the sub-layers 300₁ and 300₂) of the ring wall 300 is in a form of square-shape with the outer sidewall SWo300 and the inner sidewall SWi300 opposing to the outer sidewall SWo300 in the lateral direction (e.g. the direction X and the direction Y). That is, the second portion 32 (e.g., the sub-layers 300₁ and 300₂) and the first portion 31 (e.g., the sub-layer 300₀) share the same outer sidewall SWo300 and inner sidewall SWi300.

The formation and material of the second portion 32 (e.g., the sub-layers 300₁ and 300₂) of the ring wall 300 may be similar to or substantially identical to the forming process and materials of the metal features (e.g., the patterned conductive layers 106 with or without the optional seed layers) of the first portion 1071, of the interconnection 107 described in FIG. 3 and FIG. 4, the forming process and materials of the first portion 31 (including the sub-layer 300₀ with or without the optional seed layer) of the ring wall 300 previously described in FIG. 1 and FIG. 2 and/or the forming process and materials of the metal features (with or without the optional seed layer) of the device layer 102 previously described in FIG. 1 and FIG. 2, and thus are not repeated therein. In some embodiments, the sub-layer 300₁ of the ring wall 300 is spacing apart from the patterned conductive layer 106₁ by the dielectric layer 103₁, and the sub-layer 300₂ of the ring wall 300 is spacing apart from the patterned conductive layer 106₂ by the dielectric layer 103₂. In other words, the dielectric layer 103₁ laterally covers the sub-layer 300₁ of the ring wall 300, and the dielectric layer 103₂ laterally covers the sub-layer 300₂ of the ring wall 300. In some embodiments, an optional seed layer may be optionally formed to cover an illustrated bottom surface, an inner sidewall and an outer sidewall of the sub-layer 300₁ of the ring wall 300, and another optional seed layer may be optionally formed to cover an illustrated bottom surface, an inner sidewall and an outer sidewall of the sub-layer 300₂ of the ring wall 300. In the embodiments of which the optional seed layers are presented, the sub-layer 300₂ of the ring wall 300 is electrically coupled to the sub-layer 300₁ of the ring wall 300 through the optional seed layer interposed there-between, and the sub-layer 300₁ of the ring wall 300 is electrically coupled to the sub-layer 300₀ of the ring wall 300 through the optional seed layer interposed there-between. In the embodiments of which the optional seed layers are omitted, the sub-layer 300₂ of the ring wall 300 is electrically coupled to the sub-layer 300₁ of the ring wall 300 by direct contact, and the sub-layer 300₁ of the ring wall 300 is electrically coupled to the sub-layer 300₀ of the ring wall 300 by direct contact. In other word, the first portion 31 of the ring wall 300 is in physical contact with and electrically coupled to the second portion 32 of the ring wall 300.

For a non-limiting example, the sub-layer 300₁ of the ring wall 300 and the patterned conductive layer 106₁ of the first portion 107_{L}, which are located at the same elevation level from the surface S101t of the substrate 101, are formed in the same step. However, the disclosure is not limited thereto. Alternatively, the sub-layer 300₁ of the ring wall 300 and the patterned conductive layer 106₁ of the first portion 107_{L}, which are located at the same elevation level from the surface S101t of the substrate 101, may be formed in different steps. For another non-limiting example, the sub-layer 300₂ of the ring wall 300 and the patterned conductive layer 106₂ of the first portion 107_{L}, which are located at the same elevation level from the surface S101t of the substrate 101, are formed in the same step. However, the disclosure is not limited thereto. Alternatively, the sub-layer 300₂ of the ring wall 300 and the patterned conductive layer 106₂ of the first portion 1071, which are located at the same elevation level from the surface S101t of the substrate 101, may be formed in different steps. The number of the build-up layer(s) included in the second portion 32 of the ring wall 300 may include one, two, three or more than three, depending on the demand and the design requirement, as long as the second portion 32 of the ring wall 300 can completely penetrate through the first portion 107_{L} of the interconnect 107. For example, the number of the build-up layer(s) included in the second portion 32 of the ring wall 300 is the same as the number of the build-up layer(s) included in the first portion 107_{L} of the interconnect 107.

Referring back to FIG. 5, in some embodiments, the second portion 107_{G} of the interconnect 107 is formed over the first portion 1071, of the interconnect 107 and the second portion 32 of the ring wall 300, in accordance with a step S1008 of the method 1000 depicted in FIG. 37. For illustrative purposes, in FIG. 5, the second portion 107_{G} of the interconnect 107 may include at least two build-up layers (e.g., 103_{N-2} and 106_{N-2}, and 103_{N-1} and 106_{N-1}), however, the disclosure is not limited thereto. The number of the build-up layer(s) included in the second portion 107_{G} of the interconnect 107 may include one, two, three or more than three, depending on the demand and the design requirement, as long as the second portion 107_{G} of the interconnect 107 can fulfill the requirement of providing global interconnection between the components of the device layer 102. The second portion 107_{G} of the interconnect 107 may be referred to as the global interconnect or global interconnection of the interconnect 107.

The second portion 107_{G} of the interconnect 107 may be formed by, but not limited to, repeating the formation steps of forming the first and/or second build-up layers to form the rest of build-up layers (e.g., a third build-up layer, a fourth build-up layer, . . . , a (N−2)^{th} build-up layer (e.g., including 103_{N-2} and 106_{N-2}), and a (N−1)^{th} build-up layer (e.g., including 103_{N-1} and 106_{N-1}) after forming the second build-up layer (e.g., the 103₂ and 106₂ in FIG. 3 and FIG. 4). Upon this, the second portion 107_{G} of the interconnect 107 is manufactured. The second portion 107_{G} of the interconnect 107 may be formed on the first portion 107_{L} of the interconnect 107 by single or dual damascene process. The disclosure is not limited thereto.

In some embodiments, the second portion 107_{G} of the interconnect 107 is formed in a back-end-of-line (BEOL) fabrication processes. The planarization processes may individually include a grinding process, a CMP process, an etching process, or combinations thereof. The etching process may include a dry etching, a wet etching, or a combination thereof. The dielectric layers 103 included in the second portion 107_{G} of the interconnect 107 may be independently referred to as BEOL dielectric, a BEOL dielectric layer, or an ILD, an ILD layer, a BEOL ILD or a BEOL ILD layer, and the patterned conductive layers 106 included in the second portion 107_{G} of the interconnect 107 may be independently referred to as a BEOL metal feature, a BEOL conductive layer, a BEOL metallization layer, or a BEOL redistribution layer, sometimes.

The formation and material of the dielectric layers 103 (e.g., 103_{N-2} and 103_{N-1}) may be similar to or substantially identical to the forming process and materials of the dielectric of the device layer 102, and thus are not repeated herein for brevity. In a non-limiting example, the dielectric layers 103 (e.g., 103_{N-2} and 103_{N-1}) include oxides, the LK materials, the ELK materials, or combination thereof. In one embodiment, the materials of the dielectric layers 103 (e.g., 103_{N-2} and 103_{N-1}) included in the second portion 107_{G} are the same to each other. Alternatively, the materials of the dielectric layers 103 (e.g., 103_{N-2} and 103_{N-1}) included in the second portion 107_{G} may be different to one another, in part or all.

The formation and material of the patterned conductive layers 106 (e.g., 106_{N-2} and 106_{N-1}) may be similar to or substantially identical to the forming process and materials of the metal features of the device layer 102, and thus are not repeated herein for brevity. In a non-limiting example, the patterned conductive layers 106 (e.g., 10_{N-2} and 106_{N-1}) include Cu, Cu alloy, or the like. In one embodiment, the materials of the patterned conductive layers 106 (e.g., 106_{N-2} and 106_{N-1}) in different build-up layers included in the second portion 107_{G} are the same to each other. Alternatively, the materials of the patterned conductive layers 106 (e.g., 106_{N-2} and 106_{N-1}) in different build-up layers included in the second portion 107_{G} may be different to one another, in part or all.

In some embodiments, as illustrated in FIG. 5 and FIG. 6, a third portion 33 of the ring wall 300 is formed in the second portion 107_{G} of the interconnection 107 over the substrate 101, in accordance with the step S1008 of the method 1000 depicted in FIG. 37. The third portion 33 of the ring wall 300 may include at least two sub-layers, such as a sub-layer 300_{N-2} and a sub-layer 300_{N-1} stacked thereon, as shown in FIG. 5. In such case, the sub-layer 300_{N-2} is disposed over and electrically coupled to the sub-layer 300₂, and the sub-layer 300_{N-1} is disposed on and electrically coupled to the sub-layer 300_{N-2}, where the sub-layer 300_{N-2} is interposed between and electrically coupled to the sub-layer 300₂ and the sub-layer 300_{N-1}. The third portion 33 of the ring wall 300 may penetrate through the second portion 170_{G} of the interconnect 107, as shown in FIG. 5. In such case, the sub-layer 300_{N-2} penetrates through the (N−2)^{th} build-up layer (including 103_{N-2} and 106_{N-2}), and the sub-layer 300_{N-1} penetrates through the (N−1)^{th} build-up layer (including 103_{N-1} and 106_{N-1}). For example, a surface S3 of the sub-layer 300_{N-1} of the ring wall 300 is accessibly revealed by a surface S103_{N-1} of the dielectric layer 103_{N-1}. In some embodiments, the surface S3 of the sub-layer 300_{N-1} of the ring wall 300 is substantially level with the surface S103_{N-1} of the dielectric layer 103_{N-1}. That is, the surface S3 of the sub-layer 300_{N-1} of the ring wall 300 may be substantially coplanar to the surface S103_{N-1} of the dielectric layer 103_{N-1}, as shown in FIG. 5. The surface S3 of the sub-layer 300_{N-1} may be referred to as a surface S300t of the ring wall 300, hereinafter. In some embodiments, as shown in a plane view of FIG. 6 in conjunction with the part outlined by the dash-box A in the cross-sectional view of FIG. 5, the third portion 33 (e.g., the sub-layers 300_{N-2} and 300_{N-1}) of the ring wall 300 is in a form of square-shape with the outer sidewall SWo300 and the inner sidewall SWi300 opposing to the outer sidewall SWo300 in the lateral direction (e.g. the direction X and the direction Y). That is, the third portion 33 (e.g., the sub-layers 300_{N-2} and 300_{N-1}), the second portion 32 (e.g., the sub-layers 300₁ and 300₂) and the first portion 31 (e.g., the sub-layer 300₀) of the ring wall 300 all share the same outer sidewall SWo300 and inner sidewall SWi300. The outer sidewall SWo300 and the inner sidewall SWi300 of the ring wall 300 may be substantially vertical sidewalls, as shown in FIG. 5 and FIG. 6. Alternatively, at least one of the outer sidewall SWo300 and the inner sidewall SWi300 of the ring wall 300 may be slant. The disclosure is not limited thereto. In further alternative embodiments, at least one of the outer sidewall SWo300 and the inner sidewall SWi300 of the ring wall 300 is in a wave-shape form.

The formation and material of the third portion 33 (e.g., the sub-layers 300_{N-2} and 300_{N-1}) of the ring wall 300 may be similar to or substantially identical to the forming process and materials of the metal features (e.g., the patterned conductive layers 106 with or without the optional seed layers) of the second portion 107_{G} of the interconnection 107 described in FIG. 5 and FIG. 6, the forming process and materials of the metal features (e.g., the patterned conductive layers 106 with or without the optional seed layers) of the first portion 107_{L} of the interconnection 107 previously described in FIG. 3 and FIG. 4, the forming process and materials of the second portion 32 (including the sub-layers 300₁ and 300₂ with or without the optional seed layers) of the ring wall 300 previously described in FIG. 3 and FIG. 4, the forming process and materials of the first portion 31 (including the sub-layer 300₀ with or without the optional seed layer) of the ring wall 300 previously described in FIG. 1 and FIG. 2 and/or the forming process and materials of the metal features (with or without the optional seed layer) of the device layer 102 previously described in FIG. 1 and FIG. 2, and thus are not repeated therein. In some embodiments, the sub-layer 300_{N-2} of the ring wall 300 is spacing apart from the patterned conductive layer 106_{N-2} by the dielectric layer 103_{N-2}, and the sub-layer 300_{N-1} of the ring wall 300 is spacing apart from the patterned conductive layer 106_{N-1} by the dielectric layer 103_{N-1}. In other words, the dielectric layer 103_{N-2} laterally covers the sub-layer 300_{N-2} of the ring wall 300, and the dielectric layer 103_{N-1} laterally covers the sub-layer 300_{N-1} of the ring wall 300. In some embodiments, an optional seed layer may be optionally formed to cover an illustrated bottom surface, an inner sidewall and an outer sidewall of the sub-layer 300_{N-2} of the ring wall 300, and another optional seed layer may be optionally formed to cover an illustrated bottom surface, an inner sidewall and an outer sidewall of the sub-layer 300_{N-1} of the ring wall 300. In the embodiments of which the optional seed layers are presented, the sub-layer 300_{N-1} of the ring wall 300 is electrically coupled to the sub-layer 300_{N-2} of the ring wall 300 through the optional seed layer interposed there-between, and the sub-layer 300_{N-2} of the ring wall 300 is electrically coupled to the sub-layer 300₂ of the ring wall 300 through the optional seed layer interposed there-between (and additional sub-layers of the third potion 33, if any). In the embodiments of which the optional seed layers are omitted, the sub-layer 300_{N-1} of the ring wall 300 is electrically coupled to the sub-layer 300_{N-2} of the ring wall 300 by direct contact, and the sub-layer 300_{N-2} of the ring wall 300 is electrically coupled to the sub-layer 300₂ of the ring wall 300 by direct contacts (or by additional sub-layers (without seed layers) of the third potion 33 (if any) there-between). In other word, the second portion 32 of the ring wall 300 is in physical contact with and electrically coupled to the third portion 33 of the ring wall 300.

For a non-limiting example, the sub-layer 300_{N-2} of the ring wall 300 and the patterned conductive layer 106_{N-2} of the second portion 107_{G}, which are located at the same elevation level from the surface S101t of the substrate 101, are formed in the same step. However, the disclosure is not limited thereto. Alternatively, the sub-layer 300_{N-2} of the ring wall 300 and the patterned conductive layer 106_{N-2} of the second portion 107_{G}, which are located at the same elevation level from the surface S101t of the substrate 101, may be formed in different steps. For another non-limiting example, the sub-layer 300_{N-1} of the ring wall 300 and the patterned conductive layer 106_{N-1} of the second portion 107_{G}, which are located at the same elevation level from the surface S101t of the substrate 101, are formed in the same step. However, the disclosure is not limited thereto. Alternatively, the sub-layer 300_{N-1} of the ring wall 300 and the patterned conductive layer 106_{N-1} of the second portion 107_{G}, which are located at the same elevation level from the surface S101t of the substrate 101, may be formed in different steps. The number of the build-up layer(s) included in the third portion 33 of the ring wall 300 may include one, two, three or more than three, depending on the demand and the design requirement, as long as the third portion 33 of the ring wall 300 can completely penetrate through the second portion 107_{G} of the interconnect 107. For example, the number of the build-up layer(s) included in the third portion 33 of the ring wall 300 is the same as the number of the build-up layer(s) included in the second portion 107_{G} of the interconnect 107. Up to here, the ring wall 300 is manufactured.

The ring wall 300 may be referred to as a guard ring wall, a guard wall, a metal wall, a metallization wall, a conductive wall, a vertical wall, or an isolation wall. In some embodiments, if considering the plane view of FIG. 6 (e.g., on the X-Y plane), a cross-section of the ring wall 300 is in an annulus form of square-shape. Alternatively, in the plane view, the cross-section of the ring wall 300 may be in an annulus form of circular shape, an oval shape, an elliptical shape, a rectangular square shape, a hexagonal shape, an octangular shape, or any other suitable polygonal shape, depending on the demand and design requirements. The disclosure is not limited thereto. As illustrated in FIG. 5 and FIG. 6, in the ring wall 300, the inner sidewalls of the first portion 31, the second portion 32 and the third portion 33 are substantially aligned to each other in the direction Z, and the outer sidewalls of the first portion 31, the second portion 32 and the third portion 33 are substantially aligned to each other in the direction Z, for example.

Referring to FIG. 7 and FIG. 8, in some embodiments, a first patterning process is performed on the structure depicted in FIG. 5 and FIG. 6 to form a first opening hole OP1 in the first portion 107_{L} and the second portion 107_{G} of the interconnect 107, the device layer 102 and the substrate 101, in accordance with a step S1010 of the method 1000 depicted in FIG. 37. For example, the first opening hole OP1 is formed at (e.g., proximal to) the surface S101t of substrate 101. As shown in FIG. 7, the first opening hole OP1 may completely penetrate through the first portion 107_{L} and the second portion 107_{G} of the interconnect 107 and the device layer 102 and may further extend into the substrate 101. In some embodiments, the first opening hole OP1 extends from the surface S103_{N-1} of the dielectric layer 103_{N-1} of the second portion 107_{G} of the interconnect 107, towards the device layer 102, to a position inside the substrate 101. That is, a bottom SB1 of the first opening hole OP1 is at the position inside the substrate 101. The position may be about ½ to about ⅓ of a thickness of the substrate 101 (with the surface S101); however, the disclosure is not limited thereto. By doing so, an aspect ratio of the first opening hole OP1 is small and can be easily well-controlled, which facilitates the formation of the later-formed component (e.g., 400A, 400B, or their combinations). In such case, the first opening hole OP1 does not penetrate through the substrate 101.

The first opening hole OP1 may be disposed inside the ring wall 300, as shown in FIG. 7 and FIG. 8. That is, the first opening hole OP1 is distant from the ring wall 300, in some embodiments. For example, a distance D1 between the inner sidewall SWi300 of the ring wall 300 and a sidewall SS1 of the first opening hole OP1 is approximately from 0.2 μm to 2 μm, although other suitable thickness may alternatively be utilized. In such case, in the plane view, the first opening hole OP1 is confined by the ring wall 300 (e.g., the inner sidewall SWi300), for example. In a vertical projection on the substrate 101 along the direction Z (e.g., the plane view of FIG. 8), the first opening hole OP1 may be completely (or continuously) surrounded by (e.g. enclosed by) the ring wall 300. Due to the ring wall 300, the metal features of the first portion 107_{L} and the second portion 107_{G} of the interconnect 107 and the metal features and components of the device layer 102 can be prevented from moisture attacks during the formation of the first opening hole OP1. If considering the plane view (e.g. the X-Y plane) of the first opening hole OP1, the shape of the first opening hole OP1 may include a circular shape, as shown in FIG. 8. However, the disclosure is not limited thereto; in an alternative embodiment, the shape of the first opening hole OP1 on the plane view may be rectangular, elliptical, oval, tetragonal, octagonal or any suitable polygonal shape. As shown in FIG. 7, the sidewall SS1 of the first opening hole OP1 is substantially vertical, for example. Alternatively, the sidewall SS1 of the first opening hole OP1 may be a slant sidewall.

The first patterning process may include photolithography and etching processes. For example, a patterned mask layer (not shown) is formed on the surface S103_{N-1} of the dielectric layer 103_{N-1} of the interconnect 107 and the surface S300_{N-1} of the sub-layer 300_{N-1} of the ring wall 300. The patterned mask layer may include a photoresist and/or one or more hard mask layer. For example, the patterned mask layer has an opening (not shown) exposing a portion of the dielectric layer 103_{N-1} of the interconnect 107 surrounding by the ring wall 300. Thereafter, an etching process using the patterned mask layer as an etching mask may be performed. For example, the etching process using the patterned mask layer as the etching mask is performed to remove the portion of the interconnect 107 exposed by the patterned mask layer, so as to from the first opening hole OP1. In addition, a portion of the device layer 102 underneath the removed portion of the interconnect 107 is further removed, and a part of the substrate 101 is also removed, during the etching process. For illustrative purposes, the number of the first opening hole OP1 does not limit the disclosure, and may be designated and selected based on the demand and layout design. The etching process may include a dry etching, a wet etching, or a combination thereof.

Referring to FIG. 9 and FIG. 10, in some embodiments, a seed barrier material 4100 and a conductive material 420 are sequentially formed over the structure depicted in FIG. 7 and FIG. 8. For example, the seed barrier material 4100 is conformally formed over the surface S103_{N-1} of the second portion 107_{G} of the interconnect 107 and further extends into the first opening hole OP1 to line the sidewall SS1 and the bottom SB1 of the first opening hole OP1, and the conductive material 4200 is then formed over the seed barrier material 4100 and further fill the first opening hole OP1. As shown in FIG. 9, the seed barrier material 4100 may extend from the surface S103_{N-1} of the second portion 107_{G} of the interconnect 107 to the portion of the substrate 101 exposed by the first opening hole OP1. In some embodiments, the seed barrier material 4100 is disposed between the substrate 101 and the conductive material 4200, between the device layer 102 and the conductive material 4200, between the first portion 107_{L} of the interconnect 107 and the conductive material 4200, and between the second portion 107_{G} of the interconnect 107 and the conductive material 4200. A material of the seed barrier material 4100 may be made of TiN, Ta, TaN, Ti or the like, which may be formed by a deposition process such as CVD, PVD, ALD, or the like. A material of the conductive material 4200 may be made of copper, tungsten, aluminum, silver, combinations thereof or the like, which may be formed by a deposition process (such as CVD, PVD or the like), a plating process, combination thereof, or the like. Herein, when a layer is described as conformal or conformally formed, it indicates that the layer has a substantially equal thickness extending along the region on which the layer is formed.

Referring to FIG. 11 and FIG. 12, in some embodiments, a first planarization process is performed to the seed barrier material 4100 and the conductive material 4200 so to form a first portion 400n of a vertical connection structure (e.g., 400A in FIG. 19 and FIG. 20) in the first opening hole OP1, in accordance with a step S1012 of the method 1000 depicted in FIG. 37. For example, the seed barrier material 4100 and the conductive material 4200 are planarized to remove the excess amount thereof located on the surface S103_{N-1} of the second portion 107_{G} of the interconnect 107 to form a liner feature 410 and a conductive feature 420 inside the first opening hole OP1, where the liner feature 410 and the conductive feature 420 together constitute the first portion 400n of the vertical connection structure 400A. In some embodiments, a surface S410 of the liner feature 410 and a surface S420 of the conductive feature 420 together constitute a surface S400n of the first portion 400n. An inner surface SWi410 of the liner feature 410 is in physical contact with the conductive feature 420, while an outer surface SWo410 is in physical contact with the dielectric layers 103 of the interconnect 107, the dielectrics of the device layer 102 and the substrate 101. As shown in FIG. 11, the surface S400n of the first portion 400n (including the surface S410 of the liner feature 410 and the surface S420 of the conductive feature 420) may be substantially level with a surface (e.g., a surface S105_{N-1} of the line portion 150_{N-1}) of the patterned conductive layer 106_{N-1} and the surface S103_{N-1} of the dielectric layer 103_{N-1} of the second portion 107_{G} of the interconnect 107 and the surface S300t of the ring wall 300. For example, the surface S400n of the first portion 400n (including the surface S410 of the liner feature 410 and the surface S420 of the conductive feature 420) are substantially coplanar to the surface (e.g., S105_{N-1}) of the patterned conductive layer 106_{N-1} and the surface S103_{N-1} of the second portion 107_{G} of the interconnect 107 and the surface S300t of the ring wall 300.

As shown in FIG. 12, in the plane view, the first portion 400n of the vertical connection structure 400A is confined by the ring wall 300 (e.g., the inner sidewall SWi300), where the conductive feature 420 is confined by the liner feature 410, for example. In the vertical projection on the substrate 101 along the direction Z (e.g., the plane view of FIG. 12), the first portion 400n of the vertical connection structure 400A may be completely (or continuously) surrounded by (e.g. enclosed by) the ring wall 300, and the conductive feature 420 is separated from the dielectric layer 103_{N-1} and the ring wall 300 by the liner feature 410. In the plane view of FIG. 12, a diameter (or saying a lateral width) D420 of the conductive feature 420 of the first portion 400n is approximately from 1.0 μm to 3.0 μm, although other suitable diameter may alternatively be utilized. In the plane view of FIG. 12, a diameter (or saying a lateral width) D400n of the first portion 400n is approximately from 1.0 μm to 3.0 μm, although other suitable diameter may alternatively be utilized. In other embodiments, the liner feature 410 may be omitted. It is appreciated that the shape of the first portion 400n of the vertical connection structure 400A may correspond to and can be controlled by adjusting the shape of the first opening hole OP1.

The first planarization process may include a grinding process, a CMP process, an etching process, the like, or combinations thereof. During the first planarization process, the dielectric layer 130_{N-1} and/or the patterned conductive layer 106_{N-1} may also be planarized. After planarizing, a cleaning process may be optionally performed, for example to clean and remove the residue generated from the first planarization process. However, the disclosure is not limited thereto, and the first planarization process may be performed through any other suitable method.

Referring to FIG. 13 and FIG. 14, in some embodiments, the third portion 107_{B} of the interconnect 107 is formed over the second portion 107_{G} of the interconnect 107, the ring wall 300 and the first portion 400n of the vertical connection structure 400A, in accordance with a step S1014 of the method 1000 depicted in FIG. 37. For illustrative purposes, in FIG. 13, the third portion 107_{B} of the interconnect 107 may include a build-up layer (e.g., 103_{N} and 106_{N}). The build-up layer (e.g., 103_{N} and 106_{N}) of the third portion 107_{B} of the interconnect 107 may be an outermost layer of the interconnect 107, as shown in FIG. 13. For example, the build-up layer (e.g., 103_{N} and 106_{N}) of the third portion 107_{B} is an outermost (or topmost) build-up layer of the interconnect 107. The third portion 107_{B} of the interconnect 107 may be referred to as an bonding layer of the semiconductor device SD1, which may also considered as part of the global interconnect of the interconnect 107, sometimes.

The third portion 107_{B} of the interconnect 107 may be formed by, but not limited to, repeating the formation steps of forming the first and/or second build-up layers to form the outermost build-up layer (e.g., a (N)^{th} build-up layer (e.g., including 103_{N} and 106_{N}) after forming the (N)^{th} build-up layer (e.g., including 103_{N} and 106_{N} in FIG. 5 and FIG. 6). Upon this, the third portion 107_{B} of the interconnect 107 is manufactured. The third portion 107_{B} of the interconnect 107 may be formed on the second portion 107_{G} of the interconnect 107 by single or dual damascene process. The disclosure is not limited thereto. Up to here, the interconnect 107 is manufactured. In some embodiments, the first portion 400n of the vertical connection structure 400A is electrically coupled to the interconnect 107. As shown in FIG. 13, the via portion 104_{N} of the patterned conductive layer 106_{N} in the third portion 107_{B} of the interconnect 107 may be in physical contact with the conductive feature 420 of the first portion 400n of the vertical connection structure 400A. For example, in the vertical projection along the direction Z (e.g., FIG. 14), the via portion 104_{N} of the patterned conductive layer 106_{N} in the third portion 107_{B} of the interconnect 107 is standing on (e.g., overlapped with) the conductive feature 420 of the first portion 400n of the vertical connection structure 400A.

In some embodiments, the third portion 107_{B} of the interconnect 107 is formed in a BEOL fabrication processes. The planarization processes may individually include a grinding process, a CMP process, an etching process, or combinations thereof. The etching process may include a dry etching, a wet etching, or a combination thereof. The dielectric layer 103 (e.g., 103_{N}) included in the third portion 107_{B} of the interconnect 107 may be independently referred to as BEOL dielectric, a BEOL dielectric layer, or an ILD, an ILD layer, a BEOL ILD or a BEOL ILD layer, and the patterned conductive layer 106 (e.g., 106_{N}) included in the third portion 107_{B} of the interconnect 107 may be independently referred to as a BEOL metal feature, a BEOL conductive layer, a BEOL metallization layer, or a BEOL redistribution layer, sometimes.

The formation and material of the dielectric layer 103 (e.g., 103_{N}) may be similar to or substantially identical to the forming process and materials of the dielectric of the device layer 102, and thus are not repeated herein for brevity. In a non-limiting example, the dielectric layer 103 (e.g., 103_{N}) include oxides, the LK materials, the ELK materials, or combination thereof. The formation and material of the patterned conductive layer 106 (e.g., 106_{N}) may be similar to or substantially identical to the forming process and materials of the metal features of the device layer 102, and thus are not repeated herein for brevity. In a non-limiting example, the patterned conductive layer 106 (e.g., 106_{N}) include Cu, Cu alloy, Al, or the like.

After forming the build-up layers of the interconnect 107, the structure depicted in FIG. 13 and FIG. 14 may be flipped (turned upside down) and secured by a holding device (not shown). For example, the holding device (not shown) is adopted to secure the structure depicted in FIG. 13 and FIG. 14 by holding the interconnect 107. The holding device may be an adhesive tape, a carrier film, or a suction pad. After flipping, the substrate 101 is facing upwards and accessibly revealed, for example.

Referring to FIG. 15 and FIG. 16, in some embodiments, the substrate 101 is planarized, in accordance with a step S1016 of the method 1000 depicted in FIG. 37. For example, the back-side (e.g., the surface S101) of the substrate 101 is undergoing a planarization process to obtain a surface S101b being flat enough to facilitate sequential process(es). The surface S101b of the substrate 101 may be referred to as the non-active surface, the back-side or the rear-side of the substrate 101. The planarization process may include a grinding process, a CMP process, an etching process, the like, or combinations thereof. During the planarization process, a native oxide formed on the surface S101 of the substrate 101 may also be planarized (e.g., removed). After planarizing, a cleaning process may be optionally performed, for example to clean and remove the residue generated from the planarization process. However, the disclosure is not limited thereto, and the planarization process may be performed through any other suitable method.

Continued on FIG. 15 and FIG. 16, in some embodiments, a second patterning process is performed to the substrate 101 to form a second opening hole OP2, in accordance with a step S1018 of the method 1000 depicted in FIG. 37. For example, the second opening hole OP2 is formed at (e.g., proximal to) the surface S101b of substrate 101. As shown in FIG. 15, the second opening hole OP2 may extend from the surface S101b of the substrate 101, towards the device layer 102, to a position inside the substrate 101 that being capable of exposing the bottom SB1 and the sidewall SS1 of the first opening hole OP1. For example, the bottom SB1 of the first opening hole OP1 is completely exposed by the second opening hole OP2, while the sidewall SS1 of the first opening hole OP1 is partially exposed by the second opening hole OP2. In such case, a portion of the liner feature 410 of the first portion 400n of the vertical connection structure 400A (e.g., the outer surface SWo410 of the liner feature 410 at the bottom SB1 and the sidewall SS1 of the first opening hole OP1) is exposed by the second opening hole OP2. That is, a bottom SB2 of the second opening hole OP2 is at the position inside the substrate 101. The position may be about ½ to about ⅓ of a thickness of the substrate 101 (with the surface S101b); however, the disclosure is not limited thereto. By doing so, an aspect ratio of the second opening hole OP2 is small and can be easily well-controlled, which facilitates the formation of the later-formed component (e.g., 400A, 400B, or their combinations). In such case, the second opening hole OP2 does not penetrate through the substrate 101. In some embodiment, the aspect ratio of the second opening hole OP2 is smaller than the aspect ratio of the first opening hole OP1.

The second opening hole OP2 may be disposed over the ring wall 300, as shown in FIG. 15. That is, the second opening hole OP2 is vertically distant from the ring wall 300, in some embodiments. The second opening hole OP2 may be confined by the ring wall 300 (e.g., the outer sidewall SWo300), in the plane view. That is, a lateral size of the second opening hole OP2 may be less than or substantially equal to a lateral size of the ring wall 300. For example, in the vertical projection on the substrate 101 along the direction Z (e.g., the plane view of FIG. 16), a sidewall SS2 of the second opening hole OP2 is substantially aligned with the outer sidewall SWo300 of the ring wall 300. In such case, the sidewall SS2 of the second opening hole OP2 is overlapped with the perimeter (e.g., the outer sidewall SWo300) of the ring wall 300, in the vertical projection on the substrate 101 along the direction Z (e.g., the plane view of FIG. 16). In the embodiments of which the sidewall SS2 of the second opening hole OP2 is substantially aligned with the outer sidewall SWo300 of the ring wall 300, a width of the second opening hole OP2 is substantially equal to the outer diameter D300 of the ring wall 300. The disclosure is not limited thereto. Alternatively, in the vertical projection on the substrate 101 along the direction Z (e.g., the plane view of FIG. 15), the second opening hole OP2 may be completely (or continuously) surrounded by (e.g. enclosed by) the ring wall 300. In such case, the sidewall SS2 of the second opening hole OP2 is closer to a center (not labeled) of the ring wall 300 than the outer sidewall SWo300 of the ring wall 300 is, in the vertical projection on the substrate 101 along the direction Z. In the embodiments of which the sidewall SS2 of the second opening hole OP2 is surrounded by the outer sidewall SWo300 of the ring wall 300, a width of the second opening hole OP2 is less than the outer diameter D300 of the ring wall 300.

If considering the plane view (e.g. the X-Y plane) of the second opening hole OP2, the shape of the second opening hole OP2 may include a circular shape, as shown in FIG. 16. However, the disclosure is not limited thereto; in an alternative embodiment, the shape of the second opening hole OP2 on the plane view may be rectangular, elliptical, oval, tetragonal, octagonal or any suitable polygonal shape. As shown in FIG. 15, the sidewall SS2 of the second opening hole OP2 is substantially vertical, for example. Alternatively, the sidewall SS2 of the second opening hole OP2 may be a slant sidewall. On the other hand, as shown in FIG. 15, the bottom SB2 of the second opening hole OP2 may be below the bottom SB1 of the first opening hole OP1.

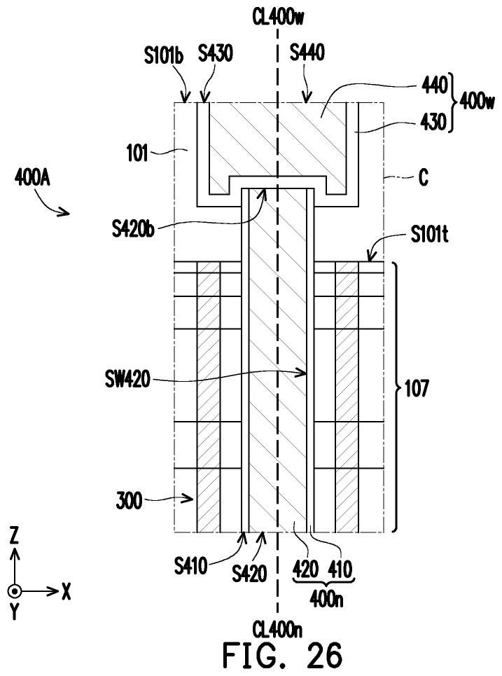

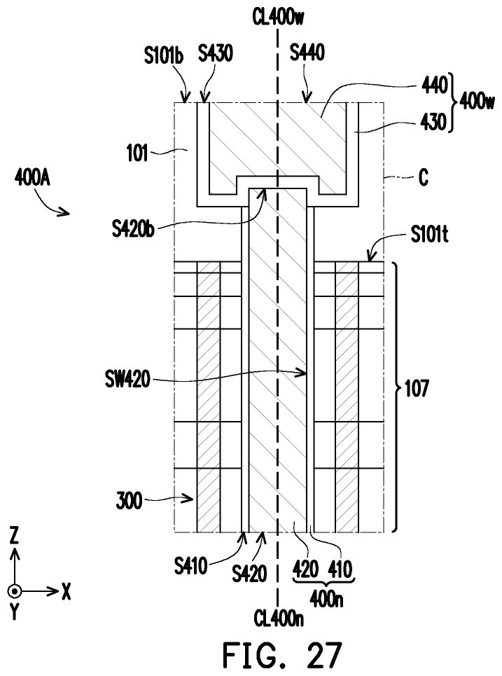

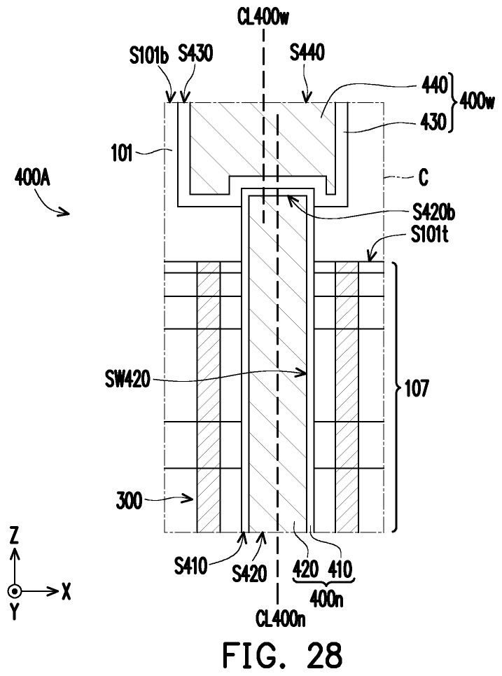

The second patterning process may include photolithography and etching processes. For example, a patterned mask layer (not shown) is formed on the surface S101b of the substrate 101. The patterned mask layer may include a photoresist and/or one or more hard mask layer. For example, the patterned mask layer has an opening (not shown) exposing a portion of the substrate 101 corresponding to the ring wall 300. Thereafter, an etching process using the patterned mask layer as an etching mask may be performed. For example, the etching process using the patterned mask layer as the etching mask is performed to remove the portion of the substrate 101 exposed by the patterned mask layer, so as to from the second opening hole OP2. In addition, the liner feature 410 of the first portion 400n exposed by the second opening hole OP2 are not removed (e.g., FIG. 25 and/or FIG. 28), during the etching process; however the disclosure is not limited thereto, in other alternative embodiments, a portion of the liner feature 410 of the first portion 400n underneath the second opening hole OP2 may be removed (e.g., FIG. 26 and/or FIG. 27). For illustrative purposes, the number of the second opening hole OP2 does not limit the disclosure, and may be designated and selected based on the demand and layout design. The etching process may include a dry etching, a wet etching, or a combination thereof.

Referring to FIG. 17 and FIG. 18, in some embodiments, a seed barrier material 4300 and a conductive material 4400 are sequentially formed over the structure depicted in FIG. 15 and FIG. 16. For example, the seed barrier material 4300 is conformally formed over the surface S101b of the substrate 101 and further extends into the second opening hole OP2 to line the sidewall SS2 and the bottom SB2 of the second opening hole OP2, and the conductive material 4400 is then formed over the seed barrier material 4300 and further fill the second opening hole OP2. As shown in FIG. 17, the seed barrier material 4300 may extend from the surface S101b of the substrate 101 to the portion of the first portion 400n of the vertical connection structure 400A exposed by the second opening hole OP2. That is, the portion of the first portion 400n of the vertical connection structure 400A exposed by the second opening hole OP2 is covered by (e.g., in physical contact with) the seed barrier material 4300. In some embodiments, the seed barrier material 4300 is disposed between the substrate 101 and the conductive material 4400 and between the first portion 400n and the conductive material 4200. The formation and material of the seed barrier material 4300 is similar to or substantially identical to the forming process and the materials of the seed barrier material 4100 previously described in FIG. 10, and the formation and material of the conductive material 4400 may be similar to or substantially identical to the forming process and the materials of the conductive material 4200 previously described in FIG. 10, and thus are not repeated herein. In a non-limiting example, the material of the seed barrier material 4300 is the same as the material of the seed barrier material 4100. Alternatively, the material of the seed barrier material 4300 is different from the material of the seed barrier material 4100. In a non-limiting example, the material of the conductive material 4400 is the same as the material of the conductive material 4200. Alternatively, the material of the conductive material 4400 is different from the material of the conductive material 4200.

Referring to FIG. 19 and FIG. 20, in some embodiments, a second planarization process is performed to the seed barrier material 4300 and the conductive material 4400 so to form a second portion 400w of the vertical connection structure 400A in the second opening hole OP2, thereby forming the vertical connection structure 400A, in accordance with a step S1020 of the method 1000 depicted in FIG. 37. For example, the seed barrier material 4300 and the conductive material 4400 are planarized to remove the excess amount thereof located on the surface S101b of the substrate 101 to form a liner feature 430 and a conductive feature 440 inside the second opening hole OP2, where the liner feature 430 and the conductive feature 440 together constitute the second portion 400w of the vertical connection structure 400A. In some embodiments, a surface S430 of the liner feature 430 and a surface S440 of the conductive feature 440 together constitute a surface S400w of the second portion 400w. As shown in FIG. 19, the surface S400w of the second portion 400w (including the surface S430 of the liner feature 430 and the surface S440 of the conductive feature 440) may be substantially level with the surface S101b of the substrate 101. For example, the surface S400w of the second portion 400w (including the surface S430 of the liner feature 430 and the surface S440 of the conductive feature 440) are substantially coplanar to the surface S101b of the substrate 101.

As shown in FIG. 20, in the plane view, the second portion 400w of the vertical connection structure 400A is confined by the ring wall 300 (e.g., the outer sidewall SWo300), where the conductive feature 440 is confined by the liner feature 430, for example. In the vertical projection on the substrate 101 along the direction Z (e.g., the plane view of FIG. 20), the second portion 400w of the vertical connection structure 400A and the ring wall 300 may be completely (or entirely) overlapped with each other, where in the cross-sectional view thereof (e.g., FIG. 19), the conductive feature 440 may be separated from the substrate 101 and the ring wall 300 by the liner feature 430. In the plane view of FIG. 20, a diameter (or saying a lateral width) D400w of the second portion 400w is approximately from 2.5 μm to 7.5 μm, although other suitable diameter may alternatively be utilized. In a non-limiting example, the diameter D400w of the second portion 400w is substantially the same as the outer diameter D300 of the ring wall 300. In other embodiments, the liner feature 430 may be omitted. It is appreciated that the shape of the second portion 400w of the vertical connection structure 400A may correspond to and can be controlled by adjusting the shape of the second opening hole OP2.

Alternatively (not shown), in the vertical projection on the substrate 101 along the direction Z, the second portion 400w of the vertical connection structure 400A may be completely (or entirely) overlapped with the ring wall 300, and the perimeter of the ring wall 300 may protrude out of the perimeter of the second portion 400w, where in the cross-sectional view thereof, the conductive feature 440 may be separated from the substrate 101 and the ring wall 300 by the liner feature 430. In such alternative embodiments, the diameter D400w of the second portion 400w is less than the outer diameter D300 of the ring wall 300.

The second planarization process may include a grinding process, a CMP process, an etching process, the like, or combinations thereof. During the second planarization process, the substrate 101 may also be planarized. After planarizing, a cleaning process may be optionally performed, for example to clean and remove the residue generated from the second planarization process. However, the disclosure is not limited thereto, and the second planarization process may be performed through any other suitable method.

Up to here, the vertical connection structure 400A including one first portion 400n and one second portion 400w is manufactured. In some embodiments, the second portion 400w is disposed over and electrically coupled to the first portion 400n, in the vertical connection structure 400A. In some embodiments, the first portion 400n and the second portion 400w of the vertical connection structure 400A are formed in different and separate steps (which may be referred to as a two-step process) in a one-to-one configuration, where the sidewall of the vertical connection structure 400A has a step-form profile, in the cross-sectional view of FIG. 19. Due to the forming process of the vertical connection structure 400A, the manufacture of the vertical connection structure 400A is easy and reliable as the aspect ratio of the first portion 400n is lowered. Owing to the first portion 400n (having the aspect ratio higher than the aspect ratio of the second portion 400w), the CD of the vertical connection structure 400A at the frontside (e.g., S101t) of the substrate 101 still maintains the same, thereby ensuring (or securing) the integration level of the semiconductor device SD1; while due to the second portion 400w (having the aspect ratio lower than the aspect ratio of the first portion 400n), the contact resistance (Rc) of the semiconductor device SD1 can be lowered. In addition, due to the two-step formation adopted for forming the first portion 400n and the second portion 400w of the vertical connection structure 400A, a thickness of the substrate 101 can be still thick enough to obtain a good thermal dissipation and a better warpage of the semiconductor device SD1. In embodiments of the disclosure, since the first portion 400n is laterally surrounded by the ring wall 300 disposed inside the interconnect 107, the metal features of the interconnect 107 can be well-protected from moisture attacks during forming the first portion 400n. In some embodiments, the vertical connection structure 400A can be utilized for transmitting signals, ground power or small power. The first portion 400n may be referred to as a narrow portion, the second portion 400w may be referred to as a narrow portion, and the vertical connection structure 400A may be referred to as a through-substrate-via or through-silicon-via (TSV), a through via, a conductive via, or a conductive pillar.

Referring to FIG. 21 and FIG. 22, in some embodiments, a bonding layer 110 is formed over the substrate 101, in accordance with a step S1022 of the method 1000 depicted in FIG. 37. For example, the bonding layer 110 is disposed over and electrically coupled to the vertical connection structure 400A for providing routing function thereto and/or providing an electrical connection with external components. In some embodiments, the bonding layer 110 is disposed on (e.g., in physical contact with) the substrate 101 and the vertical connection structure 400A, and is physical contacted and electrically connected to the vertical connection structure 400A. In such case, the bonding layer 110 may be globally disposed on the substrate 101, as shown in FIG. 21.

The formation of the bonding layer 110 may include, but not limited to, forming a blanket layer of a third dielectric material (not shown) over the substrate 101 to cover up the vertical connection structure 400A; forming a blanket layer of a fourth dielectric material (not shown) over the third dielectric material blanket layer so to sandwich the third dielectric material blanket layer between the fourth dielectric material blanket layer and the substrate 101; patterning the third dielectric material blanket layer and the fourth dielectric material blanket layer to form a first dielectric layer 108a and a second dielectric layer 108b disposed thereon, where a plurality of openings (not labeled) penetrate through the first dielectric layer 108a and the second dielectric layer 108b; forming an optional seed layer (not shown) in the openings; and forming a conductive material in the openings to form a conductive layer 109 over the optional seed layer, thereby forming the bonding layer 110. For example, as shown in FIG. 21, the metallization layer (not labeled) of the bonding layer 110 includes the conductive layer 109 and the optional seed layer (if any) standing underneath and electrically connected thereto, and is embedded in a dielectric structure 108 of the bonding layer 110, where the dielectric structure 108 includes the first dielectric layer 108a and the second dielectric layer 108b stacked thereon. For example, the conductive layer 109 is electrically coupled to the vertical connection structure 400A by direct contact. As shown in FIG. 21, the conductive layer 109 may be electrically coupled to the metal features of the interconnect 107 by the vertical connection structure 400A. In such case, the conductive layer 109 may be electrically coupled to the components of the device layer 102 by the vertical connection structure 400A and the interconnect 107.

In some embodiments, the first dielectric layer 108a and the second dielectric layer 108b have different materials. For example, the first dielectric layer 108a includes a silicon carbide (SiC) layer, a silicon nitride (Si₃N₄) layer, an aluminum oxide layer, or the like. For example, the second dielectric layer 108b includes a silicon-rich oxide (SRO) layer. In some embodiments, the second dielectric layer 108b is referred to as an inter-metal dielectric (IMD) layer which may be made of a dielectric material, such as silicon oxide, silicon nitride, silicon oxynitride, a spin-on dielectric material, or a low-k dielectric material. In some alternative embodiments, the first dielectric layer 108a and the second dielectric layer 108b have different etching selectivities. In the case, the first dielectric layer 108a may be referred to as an etching stop layer to prevent the underlying elements (e.g., the substrate 101 and/or the vertical connection structure 400A) from damage caused by the over-etching.

In some embodiments, the first dielectric material blanket layer and the second dielectric material blanket layer are patterned through a set(s) of photolithography and etching processes. The etching process may include a dry etching, a wet etching, or a combination thereof. After the etching process, a cleaning step may be optionally performed, for example, to clean and remove the residue generated from the etching process. However, the disclosure is not limited thereto, and the etching process may be performed through any other suitable method. The openings each may include a trench hole and a via hole underlying and spatially communicated to the trench hole. For example, the trench holes are formed in the second dielectric layer 108b and extend from an illustrated top surface S108b of the second dielectric layer 108b to a position inside the second dielectric layer 108b. For example, the via holes are formed in the second dielectric layer 108b and the first dielectric layer 108a and extend from the position inside the second dielectric layer 108b to an illustrated bottom surface S108a of the first dielectric layer 108a. The position may be about ½ to about ⅓ of a thickness of the second dielectric layer 108b; however, the disclosure is not limited thereto. In some embodiments, the openings includes a dual damascene structure. The formation of the openings is not limited to the disclosure. The formation of opening (with the dual damascene structure) can be formed by any suitable forming process, such as a via first approach or a trench first approach.

As shown in FIG. 21, a lateral size of the trench holes may be greater than a lateral size of the via holes. In some embodiments, a sidewall of each of the via holes is a substantially vertical sidewall. In alternative embodiments, the sidewall of each of the via holes is a slant sidewall. In some embodiments, a sidewall of each of the trench holes is a substantially vertical sidewall. In alternative embodiments, the sidewall of each of the trench holes is a slant sidewall. The sidewall of one via hole and the sidewall of a respective one trench hole may be collectively referred to as a sidewall of one opening. For illustrative purposes, the number of the openings shown in FIG. 21 does not limit the disclosure, and may be designated and selected based on the demand and layout design. As illustrated in FIG. 21, portions of the conductive layer 109 in the metallization layer formed in the trench holes may be referred to as conductive lines, conductive traces or conductive wires 109t horizontally extended (e.g., extending in a direction X and/or a direction Y), and portions of the conductive layer 109 in the metallization layer formed in the via holes may be referred to as conductive vias 109v vertically extended (e.g., extending in a direction Z). As shown in FIG. 21 and FIG. 22, the conductive vias 109v may stand on and be electrically coupled to the vertical connection structure 400A.

In some embodiments, the optional seed layer and the conductive layer 109 are sequentially formed in the openings by, but not limited to, conformally forming a blanket layer made of metal or metal alloy materials over the dielectric structure 108 and extending into the openings, so to line the sidewalls of the openings; filling the conductive material in the openings; and removing excess amount of the blanket layer made of metal or metal alloy materials and the conductive material over the illustrated top surface S108b of the second dielectric layer 108b, thereby the metallization layer including the optional seed layer and the conductive layer 109 is manufactured. The removal may be performed by a planarization process such as a mechanical grinding, a CMP, and/or an etching process. After the planarization process, a cleaning process may be optionally performed, for example, to clean and remove the residue generated from the planarization process. However, the disclosure is not limited thereto, and the planarization process may be performed through any other suitable method.

In some embodiments, the optional seed layer is referred to as a metal layer, which can be a single layer or a composite layer including a plurality of sub-layers formed of different materials. In some embodiments, the optional seed layer includes titanium, copper, molybdenum, tungsten, titanium nitride, titanium tungsten, combinations thereof, or the like. For example, the optional seed layer may include a titanium layer and a copper layer over the titanium layer. The optional seed layer may be formed using, for example, sputtering, PVD, or the like. The optional seed layer may have a thickness (as measured in the direction Z) of about 0.5 nm to about 100 nm, although other suitable thickness may alternatively be utilized.

In some embodiments, a material of the conductive material for forming the conductive layer 109 includes a suitable conductive material, such as metal and/or metal alloy. For example, the conductive material can be Al, aluminum alloys, Cu, copper alloys, or combinations thereof (e.g., AlCu), the like, or combinations thereof. In some embodiments, the conductive material is formed by plating process or any other suitable method, which the plating process may include electroplating or electroless plating, or the like. In alternative embodiments, the conductive material may be formed by deposition. The disclosure is not limited thereto. In the case, an illustrated top surface S109 of the conductive layer 109 in the metallization layer is substantially level with an illustrated top surface (e.g., S108b) of the dielectric structure 108. That is, the illustrated top surface S109 of the conductive layer 109 in the metallization layer may be substantially coplanar to the illustrated top surface (e.g., S108b) of the dielectric structure 108.

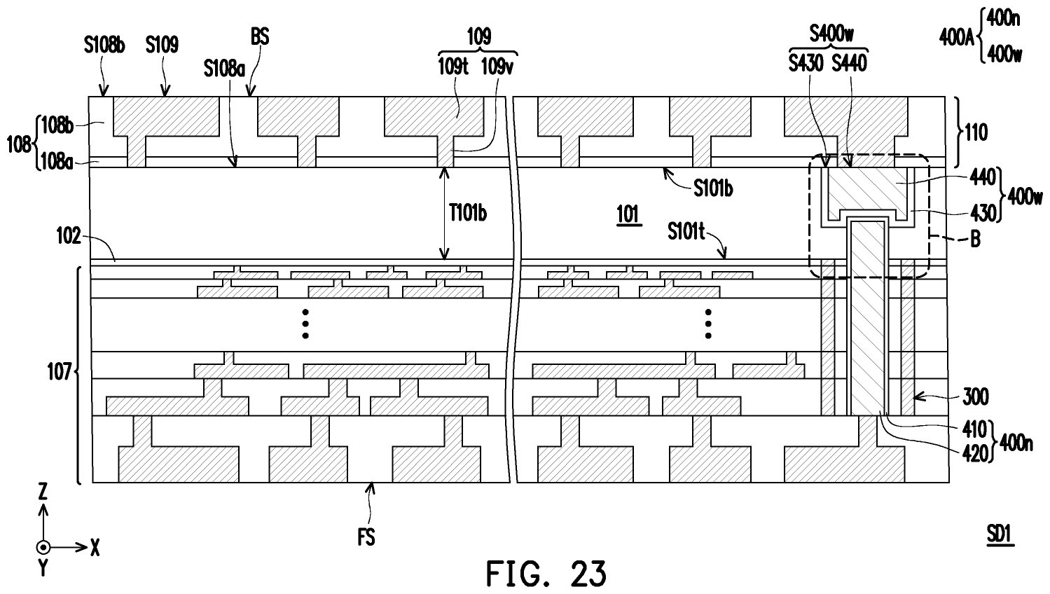

Referring to FIG. 23, in some embodiments, after the formation of the bonding layer 110, a dicing (singulation) process is performed to cut through the bonding layer 110, the substrate 101, the device layer 102 and the interconnect 107 so to form a plurality of independent and separate semiconductor devices SD1 from the structure depicted in FIG. 21 and FIG. 22. Up to here, the semiconductor device SD1 is manufactured, where the semiconductor device SD1 has a front side FS including an outermost surface of the interconnect 107 and a back side BS including an outermost surface of the bonding layer 110. The interconnect 107 may be referred to as a frontside interconnect or interconnection of the semiconductor device SD1. As shown in FIG. 23, a sidewall of the semiconductor device SD1 may be a substantially vertical sidewall, which may include a sidewall of the bonding layer 110, a sidewall of the substrate 101 and a sidewall of the interconnect 107. In such case, the sidewall of the bonding layer 110, the sidewall of the substrate 101 and the sidewall of the interconnect 107 are substantially aligned with each other in the direction Z. In some embodiments, the vertical connection structure 400A is embedded in the substrate 101 and the interconnect 107, and electrically coupled to the bonding layer 110, the interconnect 107, and the device layer 102. In one embodiment, the dicing (singulation) process is a wafer dicing process including mechanical blade sawing or laser cutting. The disclosure is not limited thereto.

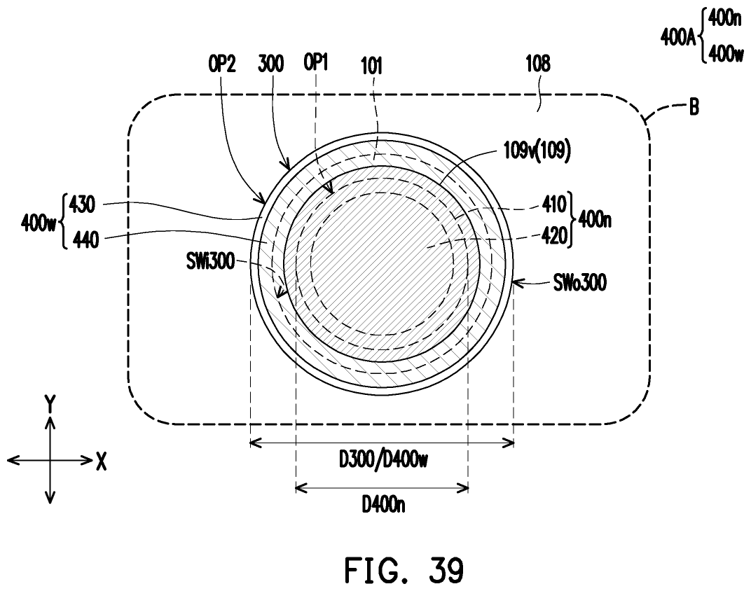

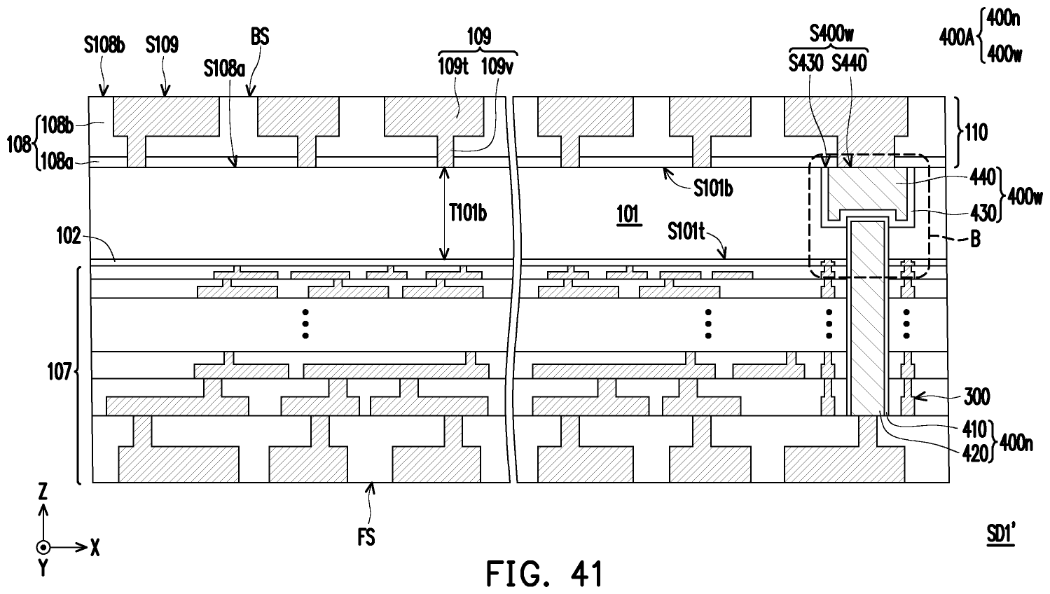

In the embodiment of the semiconductor device SD1, the cross-section of the ring wall 300 is in an annulus form of rectangular shape. However, the disclosure is not limited thereto; alternatively, in the plane view, the cross-section of the ring wall 300 may be in an annulus form of circular shape, see FIG. 39. In the embodiment of the semiconductor device SD1, the outer sidewall SWo300 and the inner sidewall SWi300 of the ring wall 300 are in a substantially vertical form, respectively. However, the disclosure is not limited thereto; alternatively, the outer sidewall SWo300 and the inner sidewall SWi300 of the ring wall 300 are in a wave-shape form, respectively; see a semiconductor device SD1′ of FIG. 41. Or, the outer sidewall SWo300 and the inner sidewall SWi300 of the ring wall 300 are in a substantially slant form, respectively. In the embodiments of slant sidewalls are adopted by the ring wall 300, the outer diameter D300 of the ring wall 300 may be tapered from the surface S103_{N-1} to the surface S101t. Or alternatively, the outer diameter D300 of the ring wall 300 may be tapered from the surface S101t to the surface S103_{N-1}.

In the embodiment of the semiconductor device SD1, the bonding layer 110 including the conductive layer 109 and the dielectric structure 108 is included and disposed at the surface S101b of the substrate 101 to be electrically coupled to the vertical connection structure 400A for providing routing function thereto and/or providing an electrical connection with external components. However, the disclosure is not limited thereto, alternatively, the bonding layer 110 may be substituted by an interconnect, see FIG. 24. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated.

In some embodiments, a semiconductor device SD2 of FIG. 24 is similar to the semiconductor device SD1 of FIG. 23; the difference is that, in the semiconductor device SD2 of FIG. 24, the bonding layer 110 is substituted by an interconnect 107′. In some embodiments, the interconnect 107′ is disposed at the surface S101b of the substrate 101 and electrically coupled to the second portion 400w of the vertical connection structure 400A, while the interconnect 107 is disposed at the surface S101t of the substrate 101 and electrically coupled to the first portion 400n of the vertical connection structure 400A, where the interconnect 107′ is electrically coupled to the interconnect 107 through the vertical connection structure 400A, and the interconnect 107′ is electrically coupled to the device layer 102 through the vertical connection structure 400A and the interconnect 107. In some embodiments, the vertical connection structure 400A is embedded in the substrate 101 and the interconnect 107, and electrically coupled to the bonding layer 110, the interconnect 107, and the device layer 102. The interconnect 107 may be referred to as a frontside interconnect or interconnection of the semiconductor device SD2, and the interconnect 107′ may be referred to as a backside interconnect or interconnection of the semiconductor device SD2.

As shown in FIG. 24, the semiconductor device SD2 may have a front side FS including an outermost surface of the interconnect 107 and a back side BS including an outermost surface of the interconnect 107′. In some embodiments, a sidewall of the semiconductor device SD2 is a substantially vertical sidewall, which may include a sidewall of the interconnect 107′, a sidewall of the substrate 101 and a sidewall of the interconnect 107. In such case, the sidewall of the interconnect 107′, the sidewall of the substrate 101 and the sidewall of the interconnect 107 are substantially aligned with each other in the direction Z. The details, formation and material of the interconnect 107′ are similar to or substantially identical to the forming process and materials of the interconnect 107, and thus are not repeated herein for brevity. In such case, the step S1022 of the method 1000 may be substituted by a step S1024 of the method 1000 in FIG. 37.

In the above embodiments, the liner feature 410 is remained on and completely covers an end surface S420b and a sidewall SW420 of the conductive feature 420, see FIG. 25 and FIG. 28. However, the disclosure is not limited thereto. In some alternative embodiments, a portion of the liner feature 410 initially disposed on the end surface S420b of the conductive feature 420 may be completely removed, see FIG. 26. For example, the end surface S420b of the conductive feature 420 is completely (or entirely) exposed by the liner feature 410, and the sidewall SW420 of the conductive feature 420 is completely (or entirely) covered by the liner feature 410. By doing so, the electrically connection between the first portion 400n and the second portion 400w can be improved. In some other embodiments, a portion of the liner feature 410 initially disposed on the end surface S420b of the conductive feature 420 may be completely removed, and a portion of the liner feature 410 initially disposed on the sidewall surface SW420 of the conductive feature 420 may be partially removed, see FIG. 27. For example, the end surface S420b of the conductive feature 420 is completely (or entirely) exposed by the liner feature 410, and the sidewall SW420 of the conductive feature 420 is partially covered by the liner feature 410. By doing so, the electrically connection between the first portion 400n and the second portion 400w can be further improved.

In the above embodiments, a central line CL400w of the second portion 400w and a central line CL400n of the first portion 400n of one vertical connection structure 400A are substantially aligned to each other, see FIG. 25 through FIG. 27. For example, the second portion 400w and the first portion 400n of one vertical connection structure 400A share a common central line (not labeled). However, the disclosure is not limited thereto. In some alternative embodiments, the central line CL400w of the second portion 400w and the central line CL400n of the first portion 400n of one vertical connection structure 400A are offset from one another, see FIG. 28.

In the semiconductor devices SD1 and SD2, only one vertical connection structure 400A is presented. However, the number of the vertical connection structure 400A may be one, two, three or more than three, depending on the demand and design requirement. The disclosure is not limited thereto.

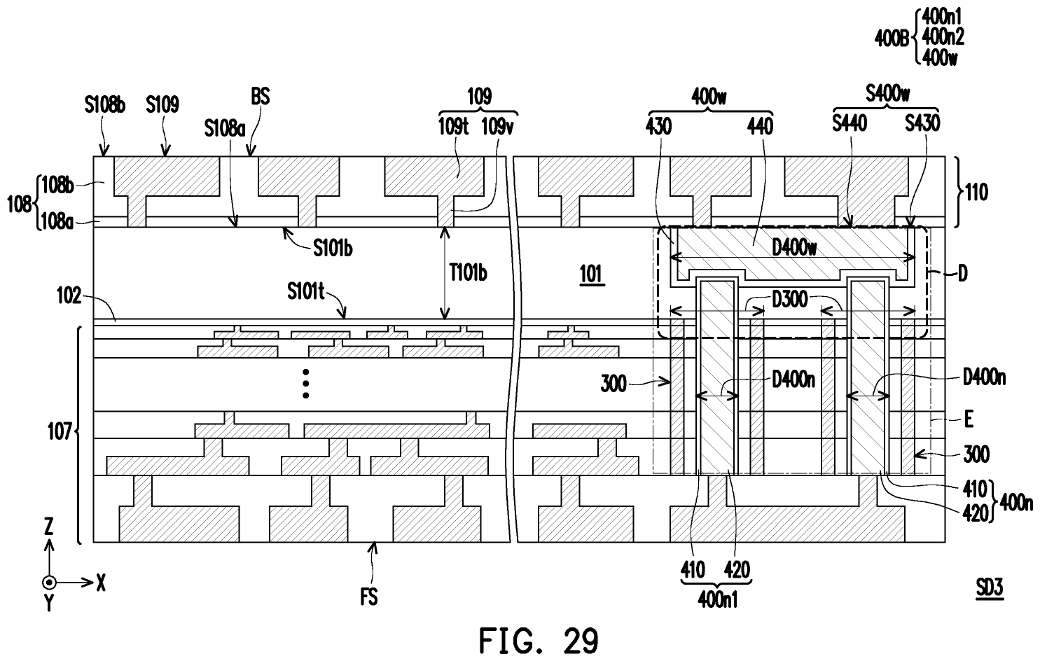

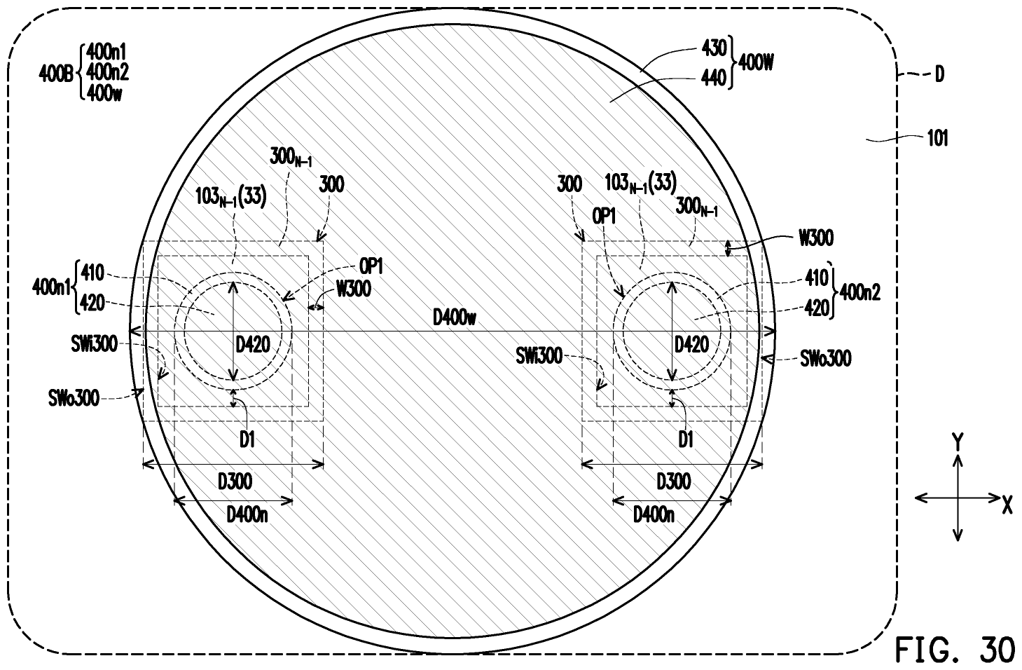

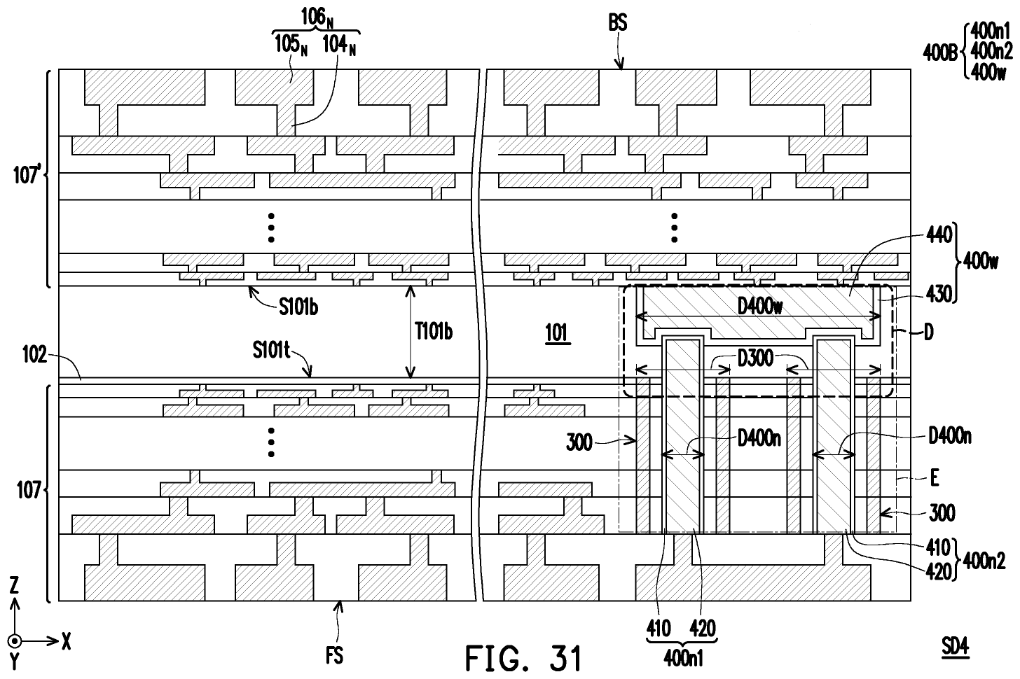

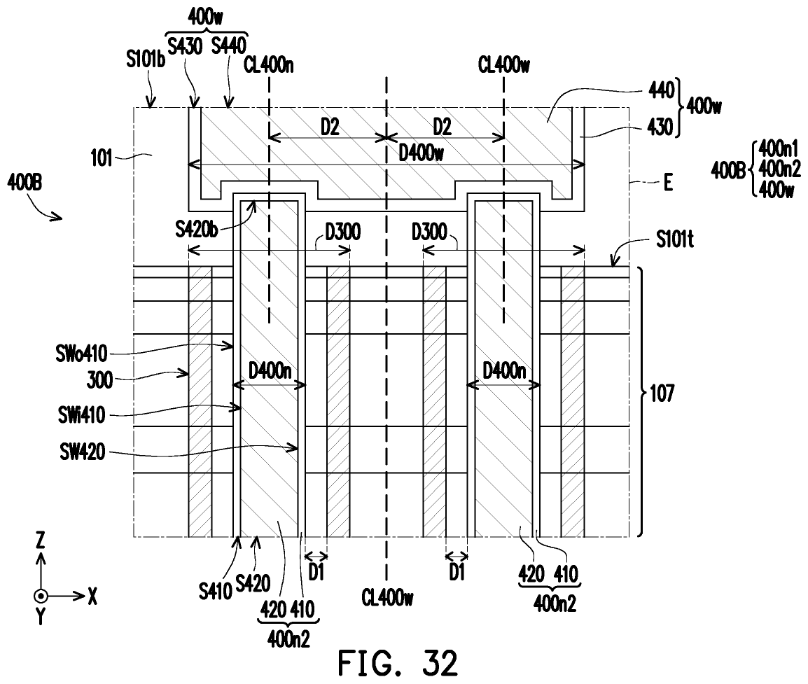

FIG. 29 and FIG. 30 are schematic plane or cross-sectional views showing a semiconductor device (e.g., SD3) in accordance with some embodiments of the disclosure, where the schematic plane view of FIG. 29 is respectively outlined by a dash-box D depicted in the schematic cross-sectional view of FIG. 30. FIG. 31 is a schematic cross-sectional view showing a semiconductor device (e.g., SD4) in accordance with alternative embodiments of the disclosure. FIG. 32 through FIG. 35 are enlarged and schematic cross-sectional views respectively showing a part (e.g., outlined by a dash-box E depicted in FIG. 29 and/or FIG. 31) of a semiconductor device (e.g., SD3 and/or SD4) in accordance with some embodiments of the disclosure. The embodiments are intended to provide further explanations but are not used to limit the scope of the disclosure. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated.

In some embodiments, a semiconductor device SD3 of FIG. 29 and FIG. 30 is similar to the semiconductor device SD1 of FIG. 23 in conjunction with FIG. 22; the difference is that, in the semiconductor device SD3 of FIG. 29 and FIG. 30, a vertical connection structure 400B is adopted, instead of the vertical connection structure 400A. The vertical connection structure 400B may include a plurality of first portions 400n and one second portion 400w vertically disposed over and electrically coupled to the plurality of first portions 400n, where the plurality of first portions 400n may be laterally arranged next to each other and respectively surrounded by (or enclosed by) a plurality of ring walls 300. Only two first portions 400n (e.g., 400n1 and 400n2) are shown in FIG. 29 and FIG. 30 for illustrative purposes, however, the disclosure is not limited thereto. The number of the first portions 400n included in the vertical connection structure 400B may be two, three or more than three, depending on the demand and design requirement. The disclosure is not limited thereto.

As shown in FIG. 29 and FIG. 30, the first portions 400n1 and 400n2 are completely surrounded by (or completely enclosed by) a respective one ring wall 300 and are arranged next to each other (e.g., offset from one another) in the vertical projection on the substrate 101, where in the direction Z, the second portion 400w is simultaneously disposed on the first portions 400n1 and 400n2 and further extends onto a part of a sidewall of each of the first portions 400n1 and 400n2, for example. In such case, the first portions 400n1 and 400n2 are electrically coupled to each other through the second portion 400w. The details, formation and material of the first portions 400n1 and 400n2 are substantially identical to the details, formation and material of the first portion 400n previously described in FIG. 1 through FIG. 12, and the details, formation and material of the first portions 400n1 and 400n2 are substantially identical to the details, formation and material of the first portion 400n previously described in FIG. 15 through FIG. 23, and thus are not repeated herein for simplicity. It is appreciated that all of the ring walls 300 in the semiconductor device SD3 can be formed simultaneously, while all of the first portions 400n1 and 400n2 in the semiconductor device SD3 can be formed simultaneously. In some embodiments, the second portion 400w of the vertical connection structure 400B is confined by a maximum distance between the outer sidewalls SWo300 of the ring walls 300 laterally surrounding the first portions 400n of the vertical connection structure 400B.

In some embodiments, the first portions 400n (e.g., 400n1 and 400n2) and the second portion 400w of the vertical connection structure 400B are formed in different and separate steps (which may be referred to as a two-step process) in a multiple-to-one configuration, where the sidewall of the vertical connection structure 400B has a step-form profile, in the cross-sectional view of FIG. 29. Due to the forming process of the vertical connection structure 400B, the manufacture of the vertical connection structure 400B is easy and reliable as the aspect ratio of the first portions 400n is lowered. Owing to the first portions 400n (having the aspect ratio higher than the aspect ratio of the second portion 400w), the CD of the vertical connection structure 400B at the frontside (e.g., S101t) of the substrate 101 still maintains the same, thereby ensuring (or securing) the integration level of the semiconductor device SD3; while due to the second portion 400w (having the aspect ratio lower than the aspect ratio of the first portions 400n), the contact resistance (Rc) of the semiconductor device SD3 can be lowered.

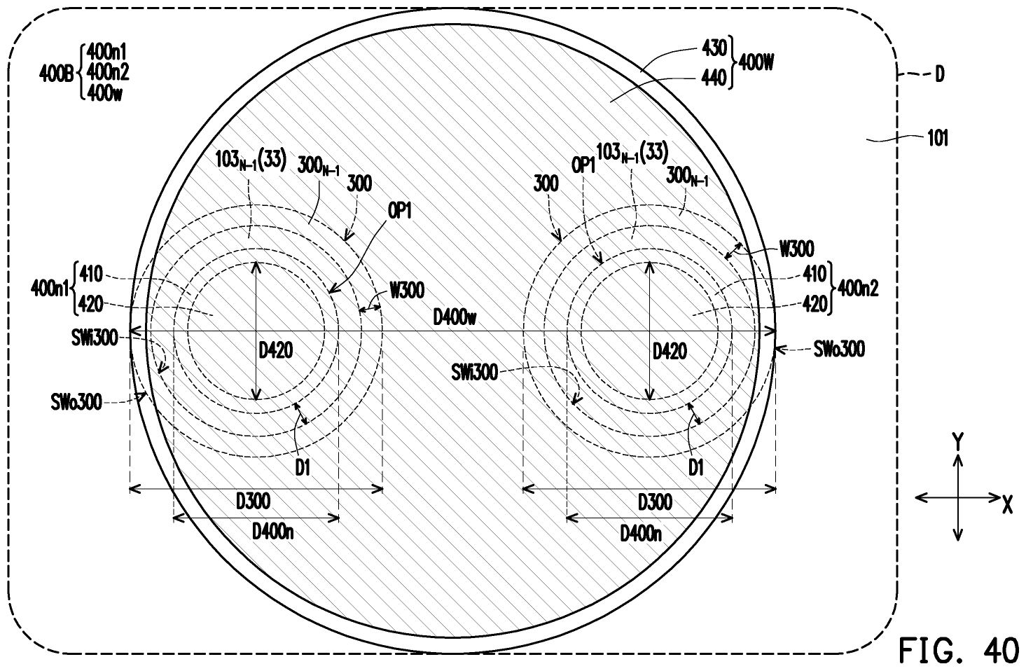

In addition, due to the two-step formation adopted for forming the first portions 400n and the second portion 400w of the vertical connection structure 400B, a thickness of the substrate 101 can be still thick enough to obtain a good thermal dissipation and a better warpage of the semiconductor device SD3. In embodiments of the disclosure, since the first portions 400n are laterally surrounded by the ring walls 300 disposed inside the interconnect 107, the metal features of the interconnect 107 can be well-protected from moisture attacks during forming the first portions 400n. In some embodiments, the vertical connection structure 400B can be utilized for transmitting signals, ground power or small power. Owing to such configuration (e.g., the multiple-to-one configuration), not only the signals, ground power or small power can be transmitted by the vertical connection structure 400B, but also a larger power can be transmitted into the semiconductor device SD3 by the vertical connection structure 400B. The vertical connection structure 400B may be referred to as a through-substrate-via or through-silicon-via (TSV), a through via, a conductive via, or a conductive pillar. In the embodiment of the semiconductor device SD3, the cross-section of the ring walls 300 is in an annulus form of rectangular shape. However, the disclosure is not limited thereto; alternatively, in the plane view, the cross-section of the ring walls 300 may be in an annulus form of circular shape, see FIG. 40. Similarly, the bonding layer 110 of the semiconductor device SD3 in FIG. 29 may be substituted by an interconnect 107′, see a semiconductor device SD4 of FIG. 31.

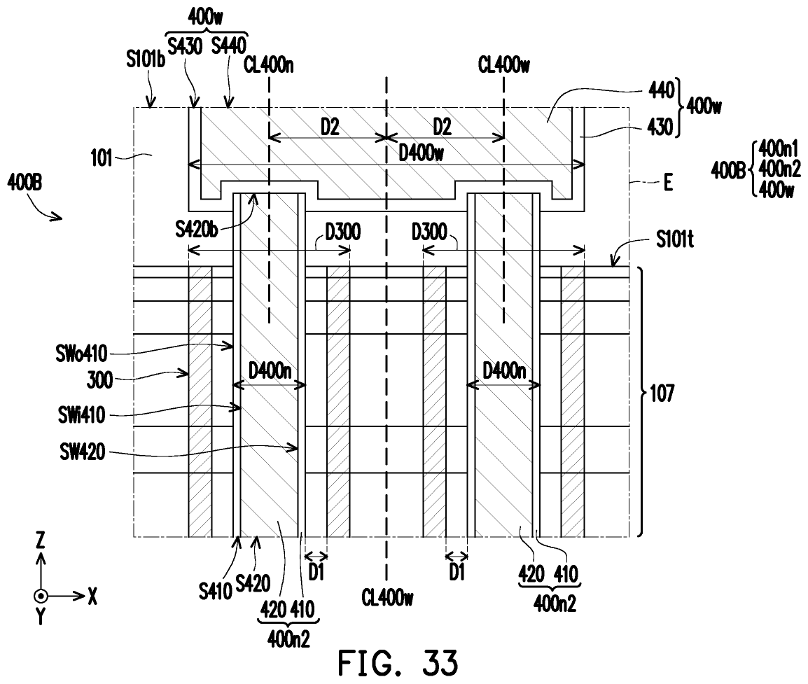

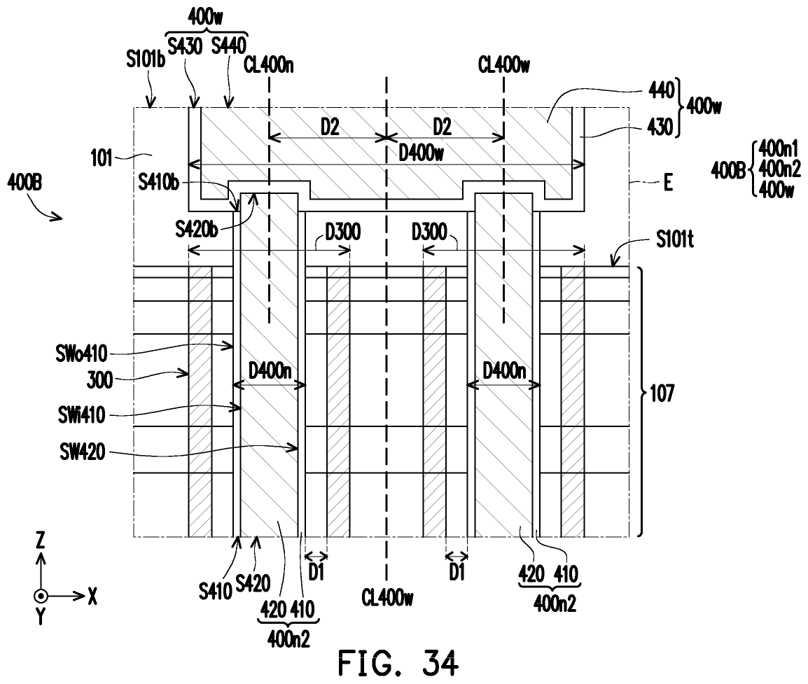

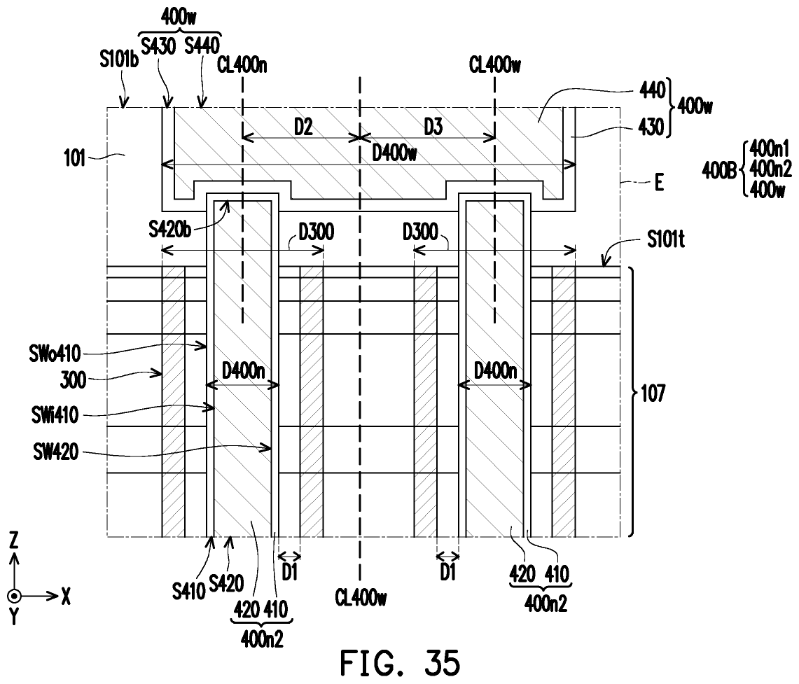

In the above embodiments, the liner feature 410 of each first portion 400n (e.g., 400n1 and/or 400n2) in the vertical connection structure 400B is remained on and completely covers an end surface S420b and a sidewall SW420 of a respective conductive feature 420, see FIG. 32 and FIG. 35. However, the disclosure is not limited thereto. In some alternative embodiments, a portion of the liner feature 410 of each first portion 400n (e.g., 400n1 and/or 400n2) in the vertical connection structure 400B initially disposed on the end surface S420b of the respective conductive feature 420 may be completely removed, see FIG. 33. For example, the end surfaces S420b of the respective conductive features 420 are completely (or entirely) exposed by the liner features 410, and the sidewalls SW420 of the respective conductive features 420 are completely (or entirely) covered by the liner features 410. By doing so, the electrically connection between the first portions 400n and the second portion 400w can be improved. In some other embodiments, a portion of the liner feature 410 of each first portion 400n (e.g., 400n1 and/or 400n2) in the vertical connection structure 400B initially disposed on the end surface S420b of the respective conductive feature 420 may be completely removed, and a portion of the liner feature 410 of each first portion 400n (e.g., 400n1 and/or 400n2) in the vertical connection structure 400B initially disposed on the sidewall surface SW420 of the respective conductive feature 420 may be partially removed, see FIG. 34. For example, the end surfaces S420b of the respective conductive features 420 are completely (or entirely) exposed by the liner features 410, and the sidewalls SW420 of the respective conductive features 420 are partially covered by the liner features 410. By doing so, the electrically connection between the first portions 400n and the second portion 400w can be further improved.

In the above embodiments, a central line CL400w of the second portion 400w and a central line CL400n of each first portion 400n (e.g., 400n1 and/or 400n2) of one vertical connection structure 400B are offset from each other, see FIG. 32 through FIG. 35. However, the disclosure is not limited thereto. In some alternative embodiments, the central line CL400w of the second portion 400w are substantially aligned with one of the central lines CL400n of the first portions 400n of one vertical connection structure 400B, not shown. That is, the second portion 400w and one and only one of the first portions 400n of one vertical connection structure 400B share a common central line (not labeled).

The central lines CL400n of the first portions 400n may be equidistant from the central line CL400w of the second portion 400w by a distance D2, as shown in FIG. 32 through FIG. 35. On the other hand, the central lines CL400n of the first portions 400n may be distant from the central line CL400w of the second portion 400w by different distances D2 and D3, as shown in FIG. 35. For example, the distance D3 is greater than the distance D2. Alternatively, the distance D3 may be less than the distance D2.

In the semiconductor devices SD3 and SD4, only one vertical connection structure 400B is presented. However, the number of the vertical connection structure 400B may be one, two, three or more than three, depending on the demand and design requirement. The disclosure is not limited thereto.

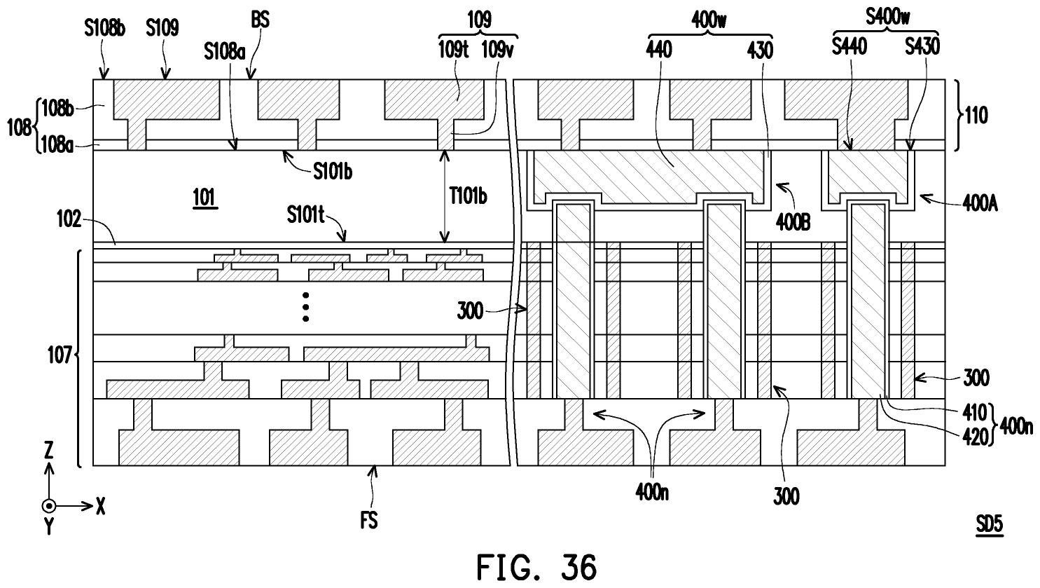

As alternatives, in the disclosure, a semiconductor device may include one or more vertical connection structure 400A and one or more vertical connection structure 400B. In a non-limiting example, a semiconductor device (not shown) include one vertical connection structure 400A and multiple vertical connection structures 400B. In another non-limiting example, a semiconductor device (not shown) include multiple vertical connection structures 400A and one vertical connection structure 400B. In another non-limiting example, a semiconductor device include one vertical connection structure 400A and one vertical connection structure 400B. FIG. 36 is a schematic cross-sectional view showing a semiconductor device (e.g., SD5) in accordance with some embodiments of the disclosure. As shown in FIG. 36, a semiconductor device SD5 may include one vertical connection structure 400A and one vertical connection structure 400B. The embodiments are intended to provide further explanations but are not used to limit the scope of the disclosure. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. In some embodiments, the semiconductor device SD5 of FIG. 36 is similar to the semiconductor device SD1 of FIG. 23 in conjunction with FIG. 22; the difference is that, in the semiconductor device SD5 of FIG. 36, in addition to the vertical connection structure 400A, the vertical connection structure 400B is further adopted. The details of the vertical connection structure 400B has been described in FIG. 29 through FIG. 35, and thus are not repeated therein.

In some embodiments, for the semiconductor device SD5, the first portions 400n and the second portions 400w of the vertical connection structures 400A and 400B are formed in different and separate steps (which may be referred to as a two-step process) in a multiple-to-one configuration, where the sidewalls of the vertical connection structures 400A and 400B have a step-form profile, in the cross-sectional view of FIG. 36. Due to the forming process of the vertical connection structures 400A and 400B, the manufacture of the vertical connection structures 400A and 400B is easy and reliable as the aspect ratio of the first portions 400n is lowered. Owing to the first portions 400n (having the aspect ratio higher than the aspect ratio of the second portions 400w), the CDs of the vertical connection structures 400A and 400B at the frontside (e.g., S101t) of the substrate 101 still maintain the same, thereby ensuring (or securing) the integration level of the semiconductor device SD5; while due to the second portions 400w (having the aspect ratio lower than the aspect ratio of the first portions 400n), the contact resistance (Rc) of the semiconductor device SD5 can be lowered.

In addition, due to the two-step formation adopted for forming the first portions 400n and the second portions 400w of the vertical connection structures 400A and 400B, a thickness of the substrate 101 can be still thick enough to obtain a good thermal dissipation and a better warpage of the semiconductor device SD5. In embodiments of the disclosure, since the first portions 400n are laterally surrounded by the ring walls 300 disposed inside the interconnect 107, the metal features of the interconnect 107 can be well-protected from moisture attacks during forming the first portions 400n. Owing to such configuration, the signals, ground power or small power can be transmitted into the semiconductor device SD5 by the vertical connection structure 400A, while a larger power can be transmitted into the semiconductor device SD5 by the vertical connection structure 400B. In some embodiments, the vertical connection structure 400B can be further utilized for transmitting signals, ground power or small power. Similarly, the bonding layer 110 of the semiconductor device SD5 in FIG. 36 may be substituted by an interconnect 107′, not shown.

The modifications described in FIG. 25 through FIG. 28 directed to the vertical connection structure 400A and/or the modifications described in FIG. 32 through FIG. 35 directed to the vertical connection structure 400B may also applied to the semiconductor device SD5. The disclosure is not limited thereto.

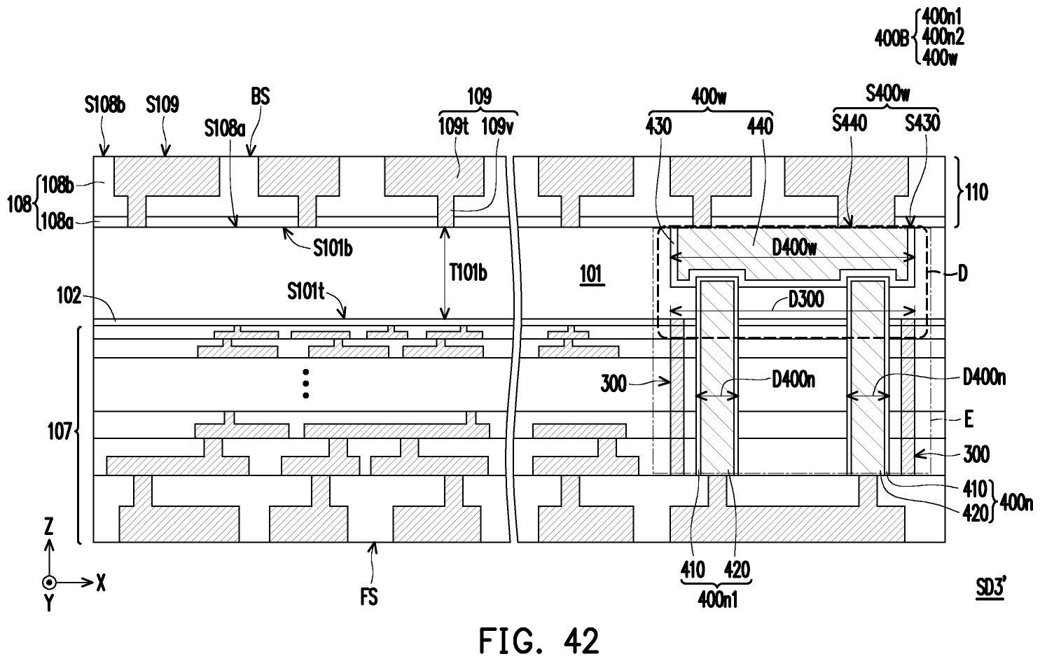

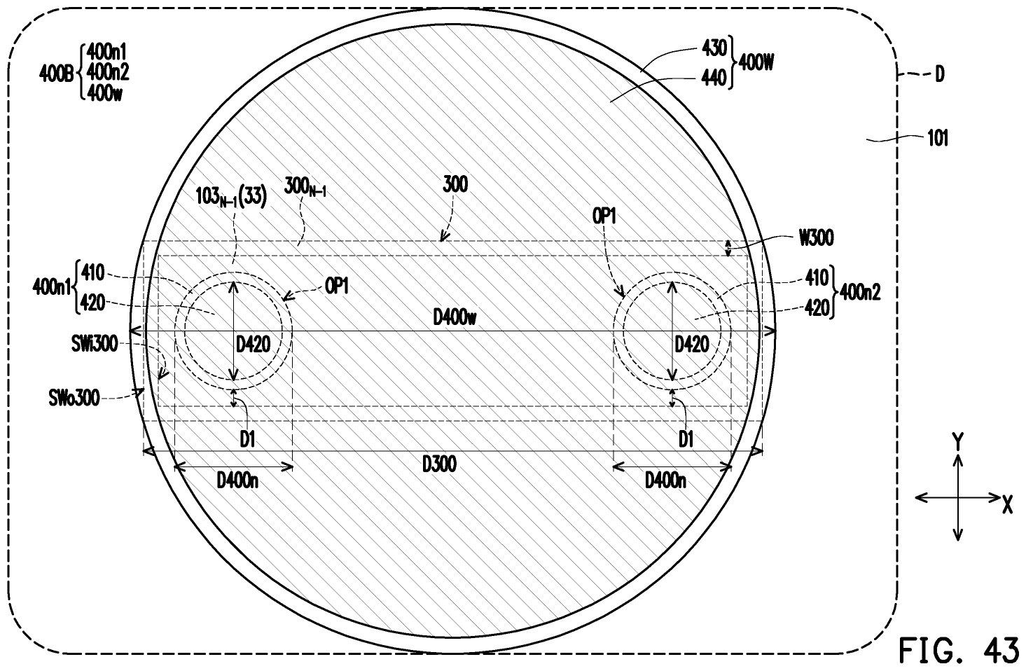

In the above embodiments, the ring wall (e.g., 300) and the vertical connection structure (e.g., 400A and/or 400B) are arranged in a one-to-one configuration. However, the disclosure is not limited thereto; alternatively, the ring wall (e.g., 300) and the vertical connection structure (e.g., 400A and/or 400B) are arranged in a one-to-multiple configuration, see a semiconductor device SD3′ of FIG. 42 and FIG. 43. For example, as shown in FIG. 42 and FIG. 23, one ring wall 300 encloses at least two vertical connection structures (e.g., 400A and/or 400B), e.g., the first portions of the at least two vertical connection structures.

In some embodiments, the semiconductor devices SD1-SD5 and modifications thereof individually may be further mounted onto another electronical component or onto a circuit structure, such as a mother board, a package substrate, a printed circuit board (PCB), a printed wiring board, and/or other carrier that is capable of carrying integrated circuits. Or, the semiconductor devices SD1-SD5 and modifications thereof individually may be or may be part of an integrated Fan-Out (InFO) package, an InFO package having a Package-on-Package (POP) structure, a chip-on-wafer-on-substrate (CoWoS) package, a flip chip package of an InFO package, or the like. The disclosure is not limited thereto.

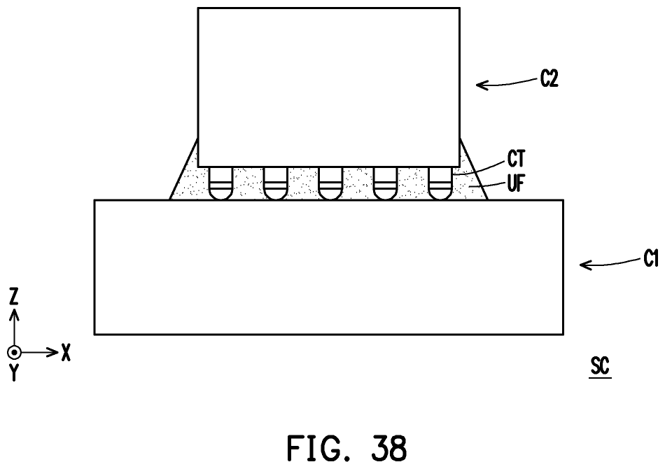

FIG. 38 is a schematic cross-sectional view showing an application of a semiconductor device (e.g., the semiconductor devices SD1-SD5 and/or modifications thereof) in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 38, in some embodiments, a component assembly SC including a first component C1 and a second component C2 disposed over the first component C1 is provided. The first component C1 may be or may include a circuit structure, such as a mother board, a package substrate, another printed circuit board (PCB), a printed wiring board, and/or other carrier that is capable of carrying integrated circuits. In some embodiments, the second component C2 mounted on the first component C1 is similar to one of the semiconductor devices the semiconductor devices SD1-SD5 and/or modifications thereof. For example, one or more second components C2 (e.g., the semiconductor devices SD1-SD5 and/or modifications thereof) may be electrically coupled to the first component C1 through a plurality of terminals CT. The terminals CT may be the conductive terminals. In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill UF may be formed by underfill dispensing, a capillary flow process, or any other suitable method. Owing to the underfill UF, a bonding strength between the first component C1 and the second component C2 is enhanced.

In accordance with some embodiments, a semiconductor device includes a substrate, an interconnect, and a vertical connection structure. The substrate has a front-side and a back-side. The interconnect is disposed over the front-side of the substrate. The vertical connection structure is embedded in the interconnect and penetrates through the substrate, and the vertical connection structure includes a first portion and a second portion. The first portion is embedded inside the interconnect and further extends into the substrate. The second portion is disposed in the substrate and extends from the back-side to the first portion, and the second portion is in contact with the first portion. An aspect ratio of the second portion is less than an aspect ratio of the first portion.

In accordance with some embodiments, a semiconductor device includes a substrate, an interconnect, a device layer, at least one first ring wall, at least one first vertical connection structure, and a metal feature. The interconnect is disposed over the substrate. The device layer is disposed between the substrate and the interconnect. The at least one first ring wall is disposed inside the device layer over the substrate and further extends into the interconnect. The at least one first vertical connection structure is embedded in and electrically coupled to the interconnect and penetrates through the substrate, and the at least one first vertical connection structure includes at least one first narrow portion and a first wide portion. The at least one first narrow portion is embedded inside the interconnect and further extends into the substrate. The first wide portion is disposed in the substrate and exposed by the substrate, the first wide portion is in contact with the at least one first narrow portion. An aspect ratio of the at least one first narrow portion is greater than an aspect ratio of the first wide portion. The metal feature is disposed over and electrically coupled to the at least one first vertical connection structure, and the substrate is between the metal feature and the device layer.

In accordance with some embodiments, a method of manufacturing a semiconductor device includes the following steps: providing a substrate having a front-side and a back-side; providing an interconnect over the front-side of the substrate; forming a ring wall inside the interconnect; forming a first portion of a vertical connection structure in the interconnect and further extending into the substrate, the first portion of the vertical connection structure being surrounded by and spacing from the ring wall and electrically coupled to the interconnect; forming a second portion of the vertical connection structure in the substrate, the second portion extending inside the substrate from a part of the first portion until reaching the back-side of the substrate, the second portion being connected to and electrically coupled to the first portion, wherein an aspect ratio of the second portion is less than an aspect ratio of the first portion; and disposing a metal feature over the substrate to be electrically coupled to the second portion of the vertical connection structure.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor device, comprising:
a substrate, having a front-side and a back-side;
an interconnect, disposed over the front-side of the substrate; and
a vertical connection structure, embedded in the interconnect and penetrating through the substrate, and comprising:
a first portion, embedded inside the interconnect and further extending into the substrate; and
a second portion, disposed in the substrate and extending from the back-side to the first portion, the second portion being in contact with the first portion,
wherein an aspect ratio of the second portion is less than an aspect ratio of the first portion.

2. The semiconductor device of claim 1, wherein the first portion is covered by the back-side of the substrate, and the second portion is covered by the front-side of the substrate.

3. The semiconductor device of claim 1, wherein along a direction perpendicular to a stacking direction of the first portion and the second portion, a first size of the first portion is less than a second size of the second portion.

4. The semiconductor device of claim 1, further comprising:
a ring wall, disposed inside the interconnect and laterally surrounding the first portion,
wherein the second portion is vertically distant from the ring wall.

5. The semiconductor device of claim 4, wherein in a vertical projection along a stacking direction of the first portion and the second portion, the first portion is confined by an innermost sidewall of the ring walls, and the second portion is confined by an outermost sidewall of the ring wall.

6. The semiconductor device of claim 4, wherein in a vertical projection along a stacking direction of the first portion and the second portion, the ring wall has an annulus shape continuously enclosing the first portion.

7. The semiconductor device of claim 1, further comprising:
an additional vertical connection structure, embedded in the interconnect and penetrating through the substrate, the additional vertical connection structure being laterally next to the vertical connection structure, and comprising:
a plurality of third portions, embedded inside the interconnect and further extending into the substrate; and
a fourth portion, disposed in the substrate and extending from the back-side to the plurality of third portions, the fourth portion being in contact with the plurality of third portions,
wherein an aspect ratio of each of the plurality of third portions is greater than an aspect ratio of the fourth portion.

8. The semiconductor device of claim 7, wherein the plurality of third portions are covered by the back-side of the substrate, and the fourth portion is covered by the front-side of the substrate.

9. The semiconductor device of claim 7, wherein along a direction perpendicular to a stacking direction of the first portion and the second portion, a third size of each of the plurality of third portions is less than a fourth size of the fourth portion.

10. The semiconductor device of claim 7, further comprising:
a plurality of additional ring walls, disposed inside the interconnect and laterally surrounding the plurality of third portions,
wherein the fourth portion is vertically distant from the plurality of additional ring walls.

11. The semiconductor device of claim 10, wherein in a vertical projection along a stacking direction of the plurality of third portions and the fourth portion, each of the plurality of third portions are confined by an innermost sidewall of a respective one of the plurality of additional ring walls, and the fourth portion is confined by a maximum distance between outermost sidewalls of the plurality of additional ring walls.

12. The semiconductor device of claim 10, wherein in a vertical projection along a stacking direction of the plurality of third portions and the fourth portion, each of the plurality of additional ring walls has an annulus shape continuously enclosing a respective third portion of the plurality of third portions.

13. The semiconductor device of claim 1, wherein the first portion comprises a plurality of first portions arranged next to each, laterally,
wherein the plurality of first portions are electrically coupled to each other through the second portion.

14. A semiconductor device, comprising:
a substrate;
an interconnect, disposed over the substrate;
a device layer, disposed between the substrate and the interconnect;
at least one first ring wall, disposed inside the device layer over the substrate and further extending into the interconnect;
at least one first vertical connection structure, embedded in and electrically coupled to the interconnect and penetrating through the substrate, and comprising:
at least one first narrow portion, embedded inside the interconnect and further extending into the substrate; and
a first wide portion, disposed in the substrate and exposed by the substrate, the first wide portion being in contact with the at least one first narrow portion,
wherein an aspect ratio of the at least one first narrow portion is greater than an aspect ratio of the first wide portion; and
a metal feature, disposed over and electrically coupled to the at least one first vertical connection structure, the substrate being between the metal feature and the device layer.

15. The semiconductor device of claim 14, wherein the at least one first narrow portion comprises a plurality of first narrow portions laterally arranged next to one another, and the at least one first ring wall comprises a plurality of first ring walls respectively surrounding and spacing apart from the plurality of first narrow portions,
wherein the first wide portion is spacing apart from the plurality of first ring walls and electrically coupled to the plurality of first narrow portions.

16. The semiconductor device of claim 14, further comprising:
a bonding layer, disposed on and electrically coupled the at least one first vertical connection structure, the substrate being between the bonding layer and the device layer, wherein the metal feature is included in the bonding layer; or
an additional interconnect, disposed on and electrically coupled the at least one first vertical connection structure, the substrate being between the additional interconnect and the device layer, wherein the metal feature is included in the additional interconnect.

17. The semiconductor device of claim 14, further comprising:
at least one second vertical connection structure, embedded in and electrically coupled to the interconnect and penetrating through the substrate, the at least one second vertical connection structure being laterally next to the at least one first vertical connection structure, and comprising:
a plurality of second narrow portions, embedded inside the interconnect and further extending into the substrate; and
a second wide portion, disposed in the substrate and exposed by the substrate, the second wide portion being in contact with the plurality of second narrow portions,
wherein an aspect ratio of each of the plurality of second narrow portions is greater than an aspect ratio of the second wide portion.

18. A method of manufacturing a semiconductor device, comprising:
providing a substrate having a front-side and a back-side;
disposed an interconnect over the front-side of the substrate;
forming a ring wall inside the interconnect;
forming a first portion of a vertical connection structure in the interconnect and further extending into the substrate, the first portion of the vertical connection structure being surrounded by and spacing from the ring wall and electrically coupled to the interconnect;
forming a second portion of the vertical connection structure in the substrate, the second portion extending inside the substrate from a part of the first portion until reaching the back-side of the substrate, the second portion being connected to and electrically coupled to the first portion, wherein an aspect ratio of the second portion is less than an aspect ratio of the first portion; and
disposing a metal feature over the substrate to be electrically coupled to the second portion of the vertical connection structure.

19. The method of claim 18,
wherein forming the ring wall inside the interconnect comprises forming a plurality of ring walls inside the interconnect, the plurality of ring walls being laterally next to each other, and
wherein forming the first portion of the vertical connection structure comprises forming a plurality of first portions in the interconnect and further extending into the substrate, the plurality of first portions being respectively surrounded by and spacing from the plurality of ring walls and electrically coupled to the interconnect, the second portion being connected to and electrically coupled to the plurality of first portions to form the vertical connection structure.

20. The method of claim 18,
wherein forming the ring wall inside the interconnect further comprises forming a plurality of additional ring walls inside the interconnect and next to the ring wall, the plurality of ring walls being laterally next to each other,
wherein forming the first portion of the vertical connection structure further comprises forming a plurality of third portions of an additional vertical connection structure in the interconnect and further extending into the substrate, the plurality of third portions of the additional vertical connection structure being respectively surrounded by and spacing from the plurality of additional ring walls and electrically coupled to the interconnect, and
wherein forming the second portion of the vertical connection structure further comprises forming a fourth portion of the additional vertical connection structure in the substrate, the fourth portion extending inside the substrate from the plurality of third portions until reaching the back-side of the substrate, the fourth portion being connected to and electrically coupled to the plurality of third portions to form the additional vertical connection structure, wherein an aspect ratio of the fourth portion is less than an aspect ratio of each of the plurality of third portions.
